(19) United States
(12) Patent Application Publication
(10) Pub. No.: US 2022/0223607 A1
(43) Pub. Date: Jul. 14, 2022

(54) SEMICONDUCTOR MEMORY DEVICE

(71) Applicant: Kioxia Corporation, Tokyo (JP)

(72) Inventors: Takuyo NAKAYAMA, Kawasaki (JP); Takashi ICHIKAWA, Saitama (JP); Yutaro OGAWA, Kawasaki (JP)

(73) Assignee: Kioxia Corporation, Tokyo (JP)

(21) Appl. No.: 17/470,948

(22) Filed: Sep. 9, 2021

(30) Foreign Application Priority Data
Jan. 13, 2021 (JP) 2021-003583

(51) Int. Cl. H01L 27/1157; H01L 27/11519; H01L 27/11524; H01L 27/11556; H01L 27/11565; H01L 27/11582

(52) U.S. Cl. CPC H01L 27/1157; H01L 27/11519; H01L 27/11582; H01L 27/11556; H01L 27/11565; H01L 27/11524

(57) ABSTRACT

A semiconductor memory device according to an embodiment includes a substrate, first conductive layers, and an insulating layer. The first conductive layers include terraced portions. The insulating layer is provided on the terraced portions. The first conductive layers include first to third layer groups. The first layer group is located the highest among the three or more layer groups. The insulating layer includes first to third portions. The first portion is sandwiched by the first layer group. The second portion is sandwiched by the second layer group. The third portion is sandwiched by the third layer group. The second portion is shifted to one side of a direction and the third portion is shifted to the other side of the direction with respect to the first portion.

### CROSS-REFERENCE TO RELATED APPLICATIONS

This application is based upon and claims the benefit of priority from Japanese Patent Application No. 2021-003583, filed Jan. 13, 2021, the entire contents of which are incorporated herein by reference.

### FIELD

Embodiments described herein relate generally to a semiconductor memory device.

### BACKGROUND

A NAND-type flash memory capable of storing data in a non-volatile manner is known.

### BRIEF DESCRIPTION OF THE DRAWINGS

FIG. 1 is a block diagram showing an example of an overall configuration of a semiconductor memory device according to an embodiment.

FIG. 2 is a circuit diagram showing an example of a circuit structure of a memory cell array included in the semiconductor memory device according to the embodiment.

FIG. 3 is a plan view showing an example of a planar layout of the memory cell array included in the semiconductor memory device according to the embodiment.

FIG. 4 is a plan view showing an example of a detailed planar layout in a memory area of the memory cell array included in the semiconductor memory device according to the embodiment.

FIG. 5 is a cross-sectional view, taken along line V-V in FIG. 4, showing an example of a cross-sectional structure in the memory area of the memory cell array included in the semiconductor memory device according to the embodiment.

FIG. 6 is a cross-sectional view, taken along line VI-VI in FIG. 5, showing an example of a cross-sectional structure of a memory pillar in the semiconductor memory device according to the embodiment.

FIG. 7 is a plan view showing an example of a detailed planar layout in a part of a hookup area of the memory cell array included in the semiconductor memory device according to the embodiment.

FIG. 8 is a cross-sectional view, taken along line VIII-VIII in FIG. 7, showing an example of a cross-sectional structure in a part of the hookup area of the memory cell array included in the semiconductor memory device according to the embodiment.

FIG. 9 is a cross-sectional view, taken along line IX-IX in FIG. 7, showing an example of a cross-sectional structure in a part of the hookup area of the memory cell array included in the semiconductor memory device according to the embodiment.

FIG. 10 is a flowchart showing an example of a method for manufacturing the semiconductor memory device according to the embodiment.

FIG. 11 is a plan view showing an example of a structure of the memory cell array included in the semiconductor memory device in the course of manufacturing according to the embodiment.

FIG. 12 is a cross-sectional view taken along line XII-XII of FIG. 11, showing an example of a structure of the semiconductor memory device in the course of the manufacturing according to the embodiment.

FIG. 13 is a plan view showing an example of a structure of the memory cell array included in the semiconductor memory device in the course of the manufacturing according to the embodiment.

FIG. 14 is a cross-sectional view taken along line XIV-XIV of FIG. 13, showing an example of a structure of the semiconductor memory device in the course of the manufacturing according to the embodiment.

FIG. 15 is a cross-sectional view taken along line XV-XV of FIG. 13, showing an example of a structure of the semiconductor memory device in the course of the manufacturing according to the embodiment.

FIG. 16 is a plan view showing an example of a structure of the memory cell array included in the semiconductor memory device in the course of the manufacturing according to the embodiment.

FIG. 17 is a cross-sectional view taken along line XVII-XVII of FIG. 16, showing an example of a structure of the semiconductor memory device in the course of the manufacturing according to the embodiment.

FIG. 18 is a cross-sectional view taken along line XVIII-XVIII of FIG. 16, showing an example of a structure of the semiconductor memory device in the course of the manufacturing according to the embodiment.

FIG. 19 is a plan view showing an example of a structure of the memory cell array included in the semiconductor memory device in the course of the manufacturing according to the embodiment.

FIG. 20 is a cross-sectional view taken along line XX-XX of FIG. 19, showing an example of a structure of the semiconductor memory device in the course of the manufacturing according to the embodiment.

FIG. 21 is a cross-sectional view taken along line XXI-XXI of FIG. 19, showing an example of a structure of the semiconductor memory device in the course of the manufacturing according to the embodiment.

FIG. 22 is a plan view showing an example of a structure of the memory cell array included in the semiconductor memory device in the course of the manufacturing according to the embodiment.

FIG. 23 is a cross-sectional view taken along line XXIII-XXIII of FIG. 22, showing an example of a structure of the semiconductor memory device in the course of the manufacturing according to the embodiment.

FIG. 24 is a cross-sectional view taken along line XXIV-XXIV of FIG. 22, showing an example of a structure of the semiconductor memory device in the course of the manufacturing according to the embodiment.

FIG. 25 is a cross-sectional view showing an example of a structure of the memory cell array included in the semiconductor memory device in the course of the manufacturing according to the embodiment.

FIG. 26 is a cross-sectional view showing an example of a structure of the memory cell array included in the semiconductor memory device in the course of the manufacturing according to the embodiment.

FIG. 27 is a plan view showing an example of a structure of the memory cell array included in the semiconductor memory device in the course of the manufacturing according to the embodiment.

FIG. 28 is a cross-sectional view taken along line XXVIII-XXVIII of FIG. 27, showing an example of a structure of the semiconductor memory device in the course of the manufacturing according to the embodiment.

FIG. 29 is a plan view showing an example of a structure of the memory cell array included in the semiconductor memory device in the course of the manufacturing according to the embodiment.

FIG. 30 is a cross-sectional view taken along line XXX-XXX of FIG. 29, showing an example of a structure of the semiconductor memory device in the course of the manufacturing according to the embodiment.

FIG. 31 is schematic views showing an example of a process of embedding an insulating film in each of the embodiment and a comparative example.

FIG. 32 is a graph showing an example of a simulation result of a void height by the insulating film embedding process.

### DETAILED DESCRIPTION

In general, according to one embodiment, a semiconductor memory device includes a substrate, a plurality of first conductive layers, a plurality of first pillars, an insulating layer, and a plurality of first contacts. The substrate includes a first area and a second area. The first area and the second area are arranged in a first direction. The first conductive layers are arranged in a second direction and separated from each other. The second direction intersects the first direction. The first conductive layers include a plurality of terraced portions. The terraced portions are provided not to overlap an upper first conductive layer in the second area. Each of the first pillars is provided to penetrate the first conductive layers in the first area. A portion at which one of the first pillars and one of the first conductive layers intersect each other functions as a memory cell. The insulating layer is provided above the terraced portions. Each of the first contacts is provided to penetrate the insulating layer. The first contacts are in contact with the terraced portions, respectively. The first conductive layers include three or more layer groups arranged in the second direction. The three or more layer groups include a first layer group, a second layer group, and a third layer group. The first layer group are located on an uppermost layer among the three or more layer groups. The insulating layer includes a first portion, a second portion, and a third portion. The first portion is sandwiched by the first layer group in a third direction which intersects each of the first direction and the second direction. The second portion is sandwiched by the second layer group in the third direction. The third portion is sandwiched by the third layer group in the third direction. Third-direction side surfaces of the first conductive layers included in the first layer group are aligned in a portion where the first portion and the first layer group are in contact. Third-direction side surfaces of the first conductive layers included in the second layer group are aligned in a portion where the second portion and the second layer group are in contact. Third-direction side surfaces of the first conductive layers included in the third layer group are aligned in a portion where the third portion and the third layer group are in contact. With respect to a center position of the first portion in the third direction, a center position of the second portion in the third direction is shifted to one side of the third direction, and a center position of the third portion in the third direction is shifted to the other side of the third direction.

Hereinafter, the embodiment will be described with reference to the accompanying drawings. The drawings are schematic or conceptual. The dimensions and ratios, etc. in the drawings are not always the same as the actual ones. In the following descriptions, constituent elements having substantially the same functions and configurations will be denoted by the same reference symbols. A numeral following characters constituting a reference symbol is used to distinguish between elements that have the same configuration that are referred to by reference symbols that have the same characters. When components having reference symbols containing the same characters string need not be distinguished from each other, these components may be referred to by a reference symbol containing the character string only.

### [1] Configuration

### [1-1] Overall Configuration of Semiconductor Memory Device 1

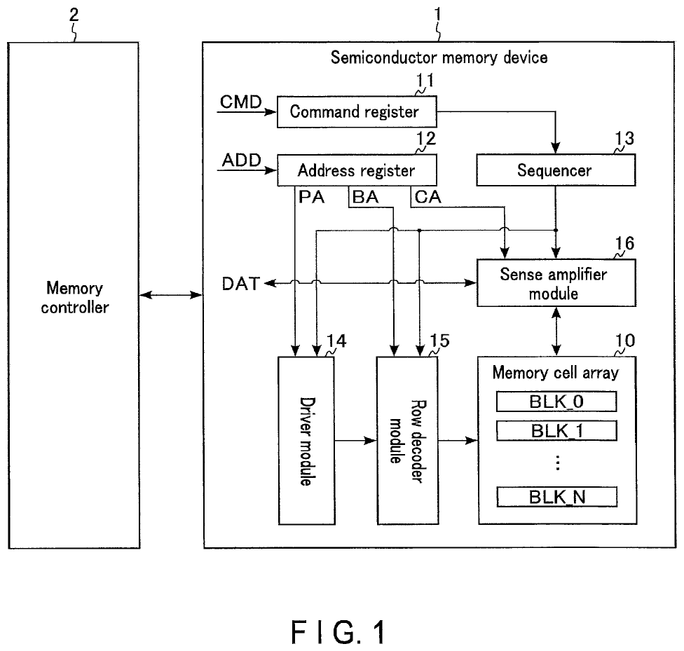

FIG. 1 is a block diagram showing an example of the overall configuration of a semiconductor memory device 1 according to the embodiment. The semiconductor memory device 1 is a NAND flash memory capable of storing data in a non-volatile manner, and is controllable by an external memory controller 2.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer equal to or greater than 1). A block BLK is a set of a plurality of memory cells capable of storing data in a nonvolatile manner, and is, for example, used as a unit of erasing data. A plurality of bit lines and word lines are provided in the memory cell array 10. Each memory cell is, for example, associated with one bit line and one word line. The structure of the memory cell array 10 will be described in detail later.

The command register 11 stores a command CMD received by the semiconductor memory device 1 from the memory controller 2. The command CMD includes, for example, an instruction for causing the sequencer 13 to execute a read, a write, an erase operations, etc.

The address register 12 stores address information ADD received by the semiconductor memory device 1 from the memory controller 2. The address information ADD includes, for example, a block address BA, a page address PA, and a column address CA. The block address BA, page address PA, and column address CA are used for selection of a block BLK, a word line, and a bit line, respectively.

The sequencer 13 controls the overall operation of the semiconductor memory device 1. For example, the sequencer 13 controls the driver module 14, row decoder module 15, and sense amplifier module 16, etc., based on a command CMD held in the command register 11, to execute the read, the write, the erase operations, etc.

The driver module 14 generates a voltage to be used for the read, the write, and the erase operations, etc. The driver module 14 applies the generated voltage to a signal line corresponding to a selected word line, for example, based on a page address PA held in the address register 12.

The row decoder module 15 selects one corresponding block BLK in the memory cell array 10, based on a block address BA held in the address register 12. The row decoder module 15 then transfers, for example, the voltage applied to the signal line corresponding to the selected word line to the selected word line in the selected block BLK.

The sense amplifier module 16 applies a desired voltage to each bit line in a write operation, in accordance with write data DAT received from the memory controller 2. In a read operation, the sense amplifier module 16 determines data stored in a memory cell based on the voltage of the bit line, and transfers the determination result to the memory controller 2 as read data DAT.

The above-described semiconductor memory device 1 and memory controller 2 may be combined into a single semiconductor device. Examples of such semiconductor devices include a memory card such as an SD™ card, and a solid state drive (SSD).

### [1-2] Circuit Configuration of Memory Cell Array 10

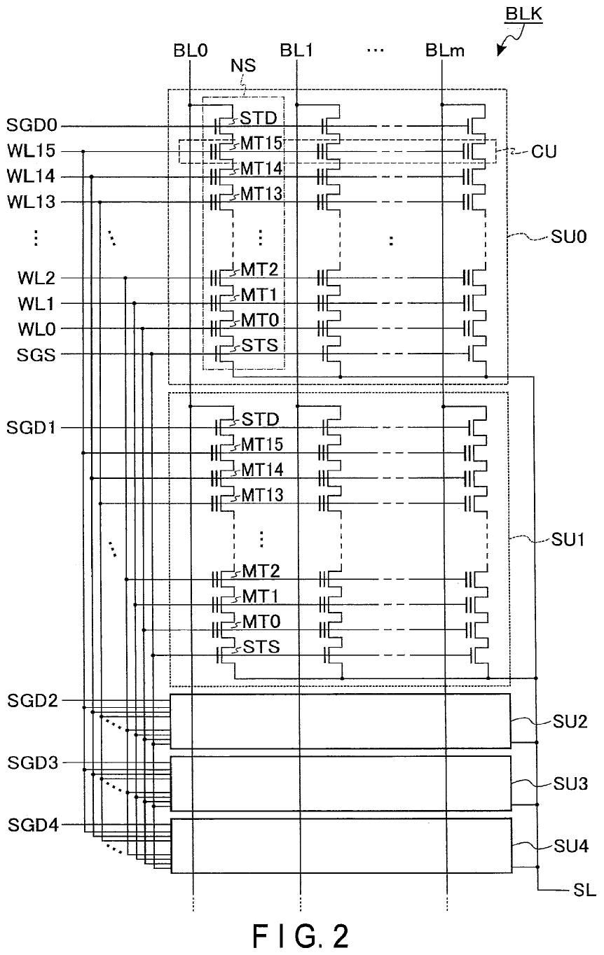

FIG. 2 is a circuit diagram showing an example of a circuit structure of the memory cell array 10 included in the semiconductor memory device 1 according to the embodiment. FIG. 2 shows one block BLK of a plurality of blocks BLK included in the memory cell array 10. As shown in FIG. 2, the block BLK includes, for example, five string units SU0 to SU4.

Each string unit SU includes a plurality of NAND strings NS respectively associated with bit lines BL0 to BLm (where m is an integer of 1 or more). Each NAND string NS includes, for example, memory cell transistors MT0 to MT15 and select transistors STD and STS. Each memory cell transistor MT includes a control gate and a charge storage layer, and stores data in a nonvolatile manner. Each of the select transistors STD and STS is used to select a string unit SU at the time of performing various operations.

In each NAND string NS, the memory cell transistors MT0 to MT15 are coupled in series. The drain of the select transistor STD is coupled to an associated bit line BL. The source of the select transistor STD is coupled to one end of a serial connection of memory cell transistors MT0 to MT15. The drain of the select transistor STS is coupled to the other end of the serial connection of memory cell transistors MT0 to MT15. The source of the select transistor STS is coupled to a source line SL.

The control gates of memory cell transistors MT0 to MT15 are coupled to word lines WL0 to WL15, respectively. The gates of a plurality of select transistors STD in the string unit SU0 are coupled to a select gate line SGD0. The gates of a plurality of select transistors STD in the string unit SU1 are coupled to a select gate line SGD1. The gates of a plurality of select transistors STD in the string unit SU2 are coupled to a select gate line SGD2. The gates of a plurality of select transistors STD in the string unit SU3 are coupled to a select gate line SGD3. The gates of a plurality of select transistors STD in the string unit SU4 are coupled to a select gate line SGD4. The gates of a plurality of select transistors STS are coupled to a select gate line SGS.

Different column addresses are respectively assigned to the bit lines BL0 to BLm. Each bit line BL is shared by the NAND strings NS, to which the same column address is assigned, among a plurality of blocks BLK. Each of select gate lines SGD0 through SGD4 and SGS and word lines WL0 to WL15 is provided for each block BLK. The source line SL is shared among a plurality of blocks BLK, for example.

A set of memory cell transistors MT coupled to a common word line WL in one string unit SU is referred to as, for example, a “cell unit CU”. For example, the storage capacity of a cell unit CU including the memory cell transistors MT, each of which stores 1-bit data, is defined as “1-page data”. The cell unit CU can have a storage capacity of 2-page data or more in accordance with the number of bits of data stored in the memory cell transistors MT.

The circuit structure of the memory cell array 10 included in the semiconductor memory device 1 according to the embodiment is not limited to the above-described structure. The number of string units SU included in each block BLK and the number of memory cell transistors MT and select transistors STD and STS included in each NAND string NS may be any number.

### [1-3] Structure of Memory Cell Array 10

An exemplary structure of the memory cell array 10 included in the semiconductor memory device 1 according to the embodiment will be described below. In the drawings to be referred to hereinafter, a direction in which the word lines WL extend is referred to as an “X direction”, a direction in which the bit lines BL extend is referred to as a “Y direction”, and a direction vertical to the surface of a semiconductor substrate 20 used for formation of the semiconductor memory device 1 is referred to as a “Z direction”. In the plan views, hatching is added as appropriate to facilitate visualization of the drawings. The hatching added to the plan views, however, may not necessarily relate to the materials or properties of the hatched structural components. In the cross-sectional views, some structures are omitted as appropriate to facilitate visualization of the drawings. The components shown in each drawing may be simplified as appropriate. Hereinafter, an even-numbered block BLK is referred to as “BLKe”, and an odd-numbered block BLK is referred to as “BLKo”.

### [1-3-1] Planar Layout of Memory Cell Array 10

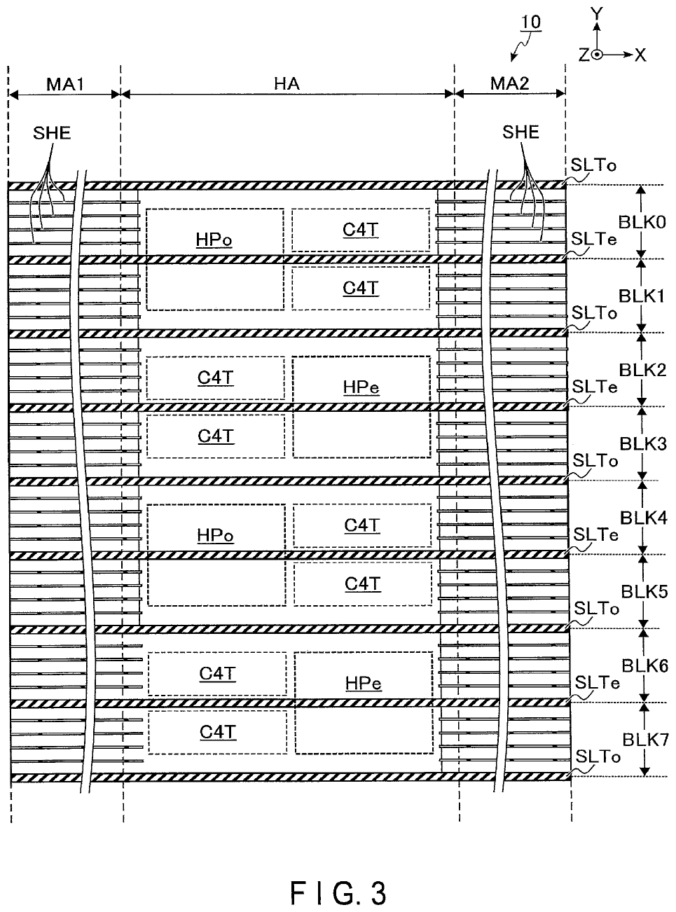

FIG. 3 is a plan view showing an example of a planar layout of the memory cell array 10 included in the semiconductor memory device 1 according to the embodiment. FIG. 3 shows an area corresponding to eight blocks BLK0 through BLK7. As shown in FIG. 3, the planar layout of the memory cell array 10 is, for example, divided into memory areas MA1 and MA2 and a hookup area HA in the X direction. Each of the memory areas MA1 and MA2 is used for data storage. Each of the memory areas MA1 and MA2 includes a plurality of NAND strings NS. The hookup area HA is arranged between the memory areas MA1 and MA2. The hookup area HA is an area provided with contacts for stacked interconnects of the memory cell array 10. The memory cell array 10 includes a plurality of slits SLT and a plurality of slits SHE.

The slits SLT, each of which includes a portion provided so as to extend along the X direction, are aligned in the Y direction. Each of the slits SLT extends across the memory areas MA1 and MA2 and the hookup area HA in the X direction. Each slit SLT has, for example, a structure into which an insulator and a plate-shaped contact are embedded. Each slit SLT divides interconnects that are adjacent to each other via the slit SLT (e.g., the word lines WL0 to WL15 and the select gate lines SGD and SGS). In this example, each of the areas sectioned by the slits SLT corresponds to one block BLK. Hereinafter, among the slits SLT aligned in the Y direction, an odd-numbered slit SLT is referred to as “SLTo” and an even-numbered slit SLT is referred to as “SLTe”.

The slits SHE are arranged in each of the memory areas MA1 and MA2. The slits SHE corresponding to the memory area MA1 are provided across the memory area MA1, and are aligned in the Y direction. The slits SHE corresponding to the memory area MA2 are provided across the memory area MA2, and are arranged in the Y direction. In this example, four slits SHE are arranged between any adjacent slits SLT. Each slit SHE has a structure into which an insulator is embedded. The slit SHE divides interconnects that are adjacent to each other via the slit SHE. It suffices that the slit SHE divides at least the select gate line SGD. In this example, each of the areas sectioned by the slits SLT and SHE corresponds to one string unit SU.

The hookup area HA includes a plurality of hookup portions HP and a plurality of contact areas C4T. Each hookup portion HP includes a plurality of contacts corresponding to stacked interconnects including a plurality of word lines WL, etc. Each contact area C4T includes a plurality of contacts that couple the interconnects above the upper portion of the memory cell array 10 to those below the memory cell array 10.

One hookup portion HP is arranged for every two blocks BLK. In other words, one hookup portion HP is arranged between adjacent slits SLTo. Furthermore, each hookup portion HP is divided by a single slit SLTe. Hereinafter, of the plurality of hookup portions HP aligned along the Y direction, an odd-numbered hookup portion HP is referred to as “HPo”, and an even-numbered hookup portion HP is referred to as “HPe”. For example, the hookup portions HPo are adjacent to the memory area MA1. The hookup portions HPe are adjacent to the memory area MA2.

A plurality of contact areas C4T are arranged in each block BLK, for example. The contact areas C4T provided in the blocks BLK in which the hookup portion HPo is arranged are arranged between the hookup portion HPo and the memory area MA2. In other words, two contact areas C4T arranged in the Y direction are arranged between the hookup portion HPo and the memory area MA2. The contact areas C4T provided in the block BLK in which the hookup portion HPe is arranged are arranged between the hookup portion HPe and the memory area MA1. In other words, two contact areas C4T arranged in the Y direction are arranged between the hookup portion HPe and the memory area MA1. The contact provided in the hookup portion HP is, for example, electrically connected to interconnects provided below the memory cell array 10, via the contact area C4T adjacent to the hookup portion HP in the Y direction.

In the memory cell array 10, the layout shown in FIG. 3 is repeatedly arranged in the Y direction. The memory cell array 10 in the semiconductor memory device 1 according to the embodiment may have another planar layout. For example, the arrangement of the hookup portions HP and the contact areas C4T in the hookup area HA may be another arrangement. The hookup portions HP may be arranged in either a zigzag manner along the Y direction as shown in FIG. 3, or in a line. The number of slits SHE arranged between adjacent slits SLT may be designed to be any number. The number of string units SU formed between adjacent slits SLT may be changed based on the number of the slits SHE arranged between adjacent slits SLT.

### [1-3-2] Structure of Memory Cell Array 10 in Memory Area MA

### Planar Layout of Memory Cell Array 10 in Memory Area MA

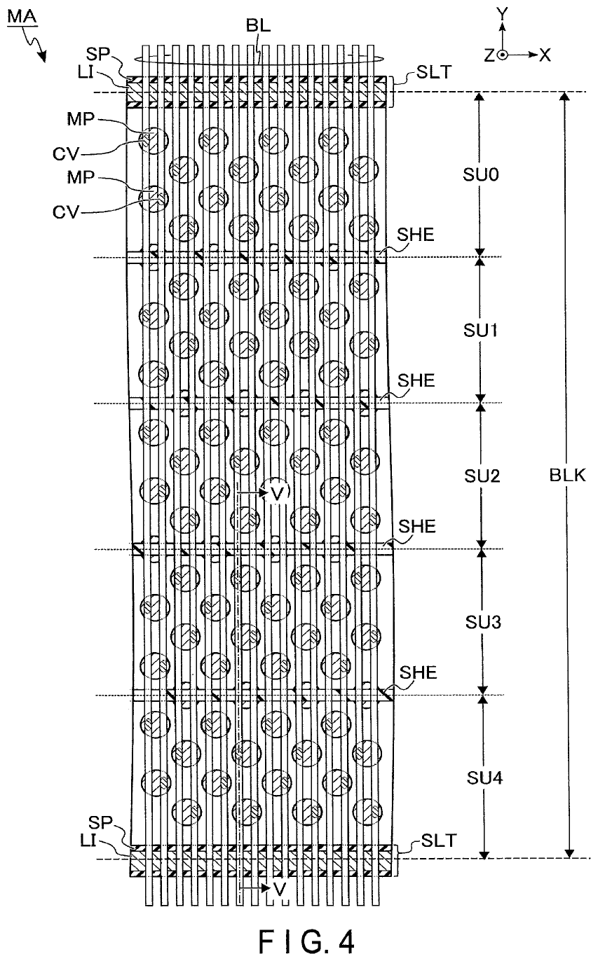

FIG. 4 is a plan view showing an example of a detailed planar layout in a memory area of the memory cell array 10 included in the semiconductor memory device 1 according to the embodiment. FIG. 4 illustrates an area that includes a single block BLK, namely string units SU0 to SU4. As shown in FIG. 4, the memory cell array 10 includes a plurality of memory pillars MP, a plurality of contacts CV, and a plurality of bit lines BL, in the memory area MA. Each slit SLT includes a contact LI and a spacer SP.

Each memory pillar MP functions as, for example, a single NAND string NS. The memory pillars MP are in, for example, a 24-row staggered arrangement in an area between two adjacent slits SLT. The memory pillars MP in the fifth row, the memory pillars MP in the tenth row, the memory pillars MP in the fifteenth row, and the memory pillars MP in the twentieth row, counting from the top of the drawing, for example, overlap a single slit SHE.

The bit lines BL, each of which includes a portion that extends in the Y direction, are aligned in the X direction. Each bit line BL is arranged so as to overlap at least one memory pillar MP in each string unit SU. In this example, one memory pillar MP is arranged so as to overlap two bit lines BL. One of a plurality of bit lines BL that overlap a memory pillar MP and the memory pillar MP are electrically coupled via a contact CV.

For example, a contact CV is omitted between a memory pillar MP in contact with a slit SHE and a bit line BL. In other words, a contact CV is omitted between a memory pillar MP in contact with two different select gate lines SGD and a bit line BL. The number and arrangement of the memory pillars MP, the slits SHE, etc. between adjacent slits SLT are not limited to the configuration described with reference to FIG. 4, and may be suitably varied. The number of bit lines BL that overlap each memory pillar MP can be freely designed.

The contact LI is a conductor including a portion that extends in the X direction. The spacer SP is an insulator that is provided on a side surface of the contact LI. The contact LI is sandwiched by the spacers SP. The contact LI and a conductor (e.g., the word lines WL0 to WL15, and the select gate lines SGD and SOS) adjacent to the contact LI in the Y direction are distanced and insulated by the spacer SP.

### (Cross-Sectional Structure of Memory Cell Array 10 in Memory Area MA

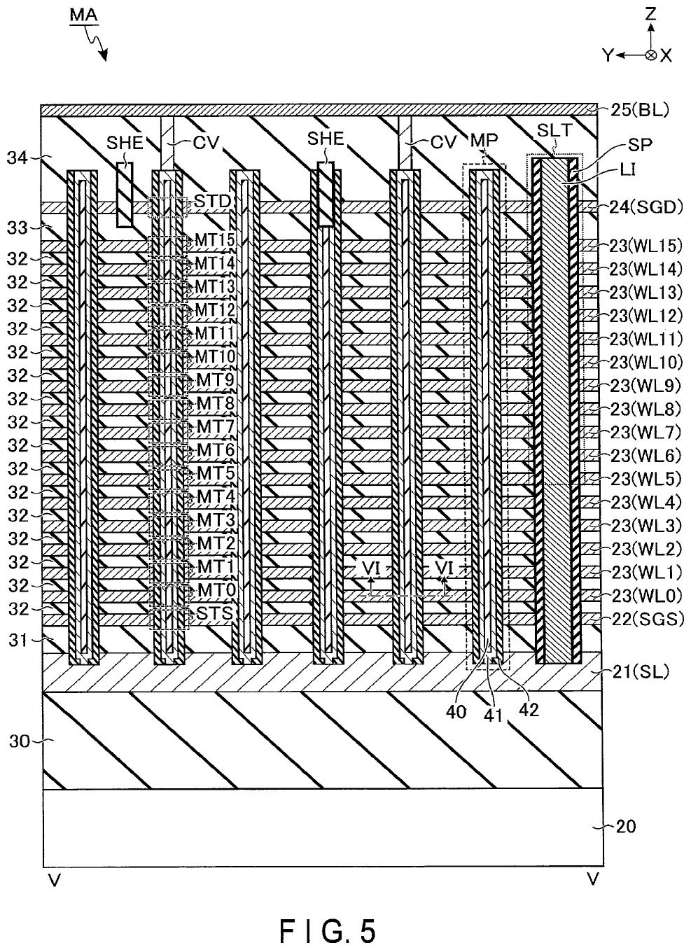

FIG. 5 is a cross-sectional view, taken along line V-V in FIG. 4, showing an example of a cross-sectional structure in the memory area MA of the memory cell array 10 included in the semiconductor memory device 1 according to the embodiment. As shown in FIG. 5, the memory cell array 10 further includes a semiconductor substrate 20, conductive layers 21 to 25, and insulating layers 30 to 34.

Specifically, the insulating layer 30 is provided on the semiconductor substrate 20. Although illustration is omitted, the insulating layer 30 includes, for example, circuitry corresponding to the row decoder module 15, the sense amplifier module 16, etc.

The conductive layer 21 is provided on the insulating layer 30. The conductive layer 21 is formed in, for example, a plate-like shape extending along the XY plane, and is used as a source line SL. The conductive layer 21 contains, for example, phosphorous-doped silicon.

The insulating layer 31 is provided on the conductive layer 21. The conductive layer 22 is provided on the insulating layer 31. The conductive layer 22 is formed in, for example, a plate-like shape extending along the XY plane, and is used as a select gate line SGS. The conductive layer 22 contains, for example, tungsten.

The insulating layers 32 and the conductive layers 23 are alternately stacked on the conductive layer 22. A conductive layer 23 has a plate-like shape expanding along the XY plane for example. The stacked conductive layers 23 are, in order from the side of the semiconductor substrate 20, used as word lines WL0 to WL15. The conductive layers 23 contain, for example, tungsten.

The insulating layer 33 is provided on the uppermost conductive layer 23. The conductive layer 24 is provided on the insulating layer 33. The conductive layer 24 is formed into, for example, a plate shape extending along the XY plane, and is used as a select gate line SGD. The conductive layer 24 contains, for example, tungsten.

The insulating layer 34 is provided on the conductive layer 24. The insulating layer 34 may be constituted by a plurality of insulating layers. The conductive layer 25 is provided on the insulating layer 34. The conductive layer 25 is formed into, for example, a line extending in the Y direction and is employed as a bit line BL. That is, a plurality of conductive layers 25 are aligned in the X direction in an unillustrated region. The conductive layers 25 contain, for example, copper.

Each of the memory pillars MP extends in the Z direction, penetrating the insulating layers 31 to 33 and the conductive layers 22 to 24. A bottom portion of the memory pillar MP is in contact with the conductive layer 21. A portion in which the memory pillar MP and the conductive layer 22 intersect each other functions as a select transistor STS. A portion in which the memory pillar MP and one conductive layer 23 intersect each other functions as one memory cell transistor MT. A portion in which the memory pillar MP and the conductive layer 24 intersect each other functions as a select transistor STD.

Each memory pillar MP includes, for example, a core member 40, a semiconductor layer 41, and a deposited film 42. The core member 40 is provided so as to extend along the Z direction. For example, a top end of the core member 40 is included in a layer above the conductive layer 24, and a bottom end of the core member 40 reaches the conductive layer 21. The semiconductor layer 41 surrounds the core member 40. Part of the semiconductor layer 41 is in contact with the conductive layer 21 at a lower portion of the memory pillar MP. The deposited film 42 covers a side surface and a bottom surface of the semiconductor layer 41, except for a portion in which the semiconductor layer 41 and the conductive layer 21 are in contact with each other. The core member 40 contains an insulator, for example silicon oxide. The semiconductor layer 41 contains, for example, silicon.

A pillar-shaped contact CV is provided on the semiconductor layer 41 in the memory pillar MP. In the illustrated area, two contacts CV, respectively corresponding to two of the six memory pillars MP, are shown. In the memory area MA, to a memory pillar MP which does not overlap the slit SHE and to which a contact CV is not coupled, a contact CV is coupled in an unillustrated area.

A single conductive layer 25, i.e., a single bit line BL, is in contact with the upper surface of the contact CV. In each space sectioned by the slits SLT and SHE, one contact CV is coupled to the single conductive layer 25. That is, the memory pillar MP arranged between any adjacent slits SLT and SHE and the memory pillar MP arranged between any two adjacent slits SHE are electrically coupled to each conductive layer 25.

The slit SLT includes, for example, a portion provided along the XZ plane, and divides the conductive layers 22 to 24. In the slit SLT, the contact LI is provided along the slit SLT. A part of a top end of the contact LI is in contact with the insulating layer 34. A bottom end of the contact LI is in contact with the conductive layer 21. The contact LI is used as, for example, part of the source line SL. The spacer SP is provided at least between the contact LI and the conductive layers 22 to 24. The contact LI and the conductive layers 22 to 24 are distanced and insulated by the spacer SP.

The slit SHE includes, for example, a portion provided along the XZ plane, and divides at least the conductive layer 24. A top end of the slit SHE is in contact with the insulating layer 34. A bottom end of the slit SHE is in contact with the insulating layer 33. The slit SHE contains, for example, an insulator such as a silicon oxide. The top end of the slit SHE may be designed to be aligned or unaligned with a top end of the slit SLT. An upper end of the slit SHE and an upper end of the memory pillar MP may be either aligned or not aligned.

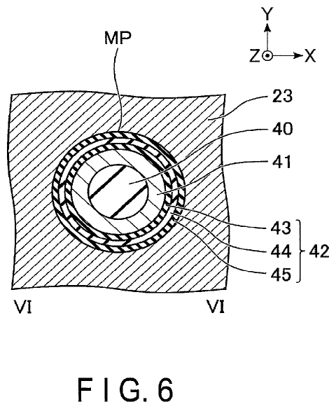

FIG. 6 is a cross-sectional view, taken along line VI-VI in FIG. 5, showing an example of a cross-sectional structure of the memory pillar MP in the semiconductor memory device 1 according to the embodiment. FIG. 6 shows a cross-sectional structure of the memory pillar MP in a layer that is parallel to the surface of the semiconductor substrate 20 and that includes a conductive layer 23. As shown in FIG. 6, the deposited film 42 includes, for example, a tunnel insulating film 43, an insulating film 44, and a block insulating film 45.

In the cross section including a conductive layer 23, the core member 40 is provided in the middle of the memory pillar MP. The semiconductor layer 41 surrounds the side surface of the core member 40. The tunnel insulating film 43 surrounds a side surface of the semiconductor layer 41. The insulating film 44 surrounds the side surface of the tunnel insulating film 43. The block insulating film 45 surrounds the side surface of the insulating film 44. A conductive layer 23 surrounds the side surface of the block insulating film 45. Each of the tunnel insulating film 43 and the block insulating film 45 contains, for example, silicon oxide. The insulating film 44 contains, for example, silicon nitride.

In the above-described memory pillar MP, the semiconductor layer 41 is used as a channel (current path) for the memory cell transistors MT0 to MT15 and the select transistors STD and STS. The insulating film 44 is used as a charge storage layer of the memory cell transistors MT. The semiconductor memory device 1 can pass an electric current through the memory pillar MP between the bit line BL and the contact LI by turning on the memory cell transistors MT0 to MT15 and the select transistors STD and

STS.

### [1-3-3] Structure of Memory Cell Array 10 in Hookup Area HA

### Planar Layout of Memory Cell Array 10 in Hookup Area HA

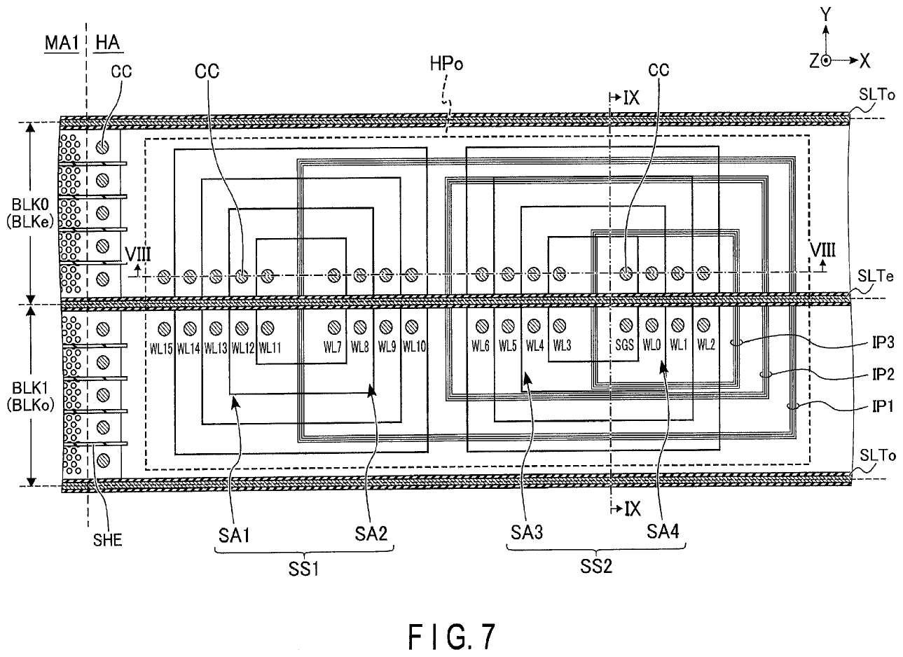

FIG. 7 is a plan view showing an example of a detailed planar layout in part (hookup portion HPo) of a hookup area HA of the memory cell array 10 included in the semiconductor memory device 1 according to the embodiment. FIG. 7 shows the hookup portion HPo and a part of the memory area MA1 in the area of adjacent blocks BLK0 (BLKe) and BLK1 (BLKo). As shown in FIG. 7, in the hookup portion HPo, each of a select gate line SGS, word lines WL0 to WL15, and a select gate line SGD includes a portion that does not overlap its upper interconnect layer (conductive layer) (hereinafter “terraced portion”). The hookup portion HPo includes stepped areas SA1, SA2, SA3, and SA4 aligned along the X direction.

The shape of the portion not covered by the upper interconnect layers in the hookup portion HPo resembles a step, terrace, rimstone, etc. Specifically, steps are individually provided between the select gate line SGS and the word line WL0, between the word line WL0 and the word line WL1, . . . , between the word line WL14 and the word line WL15, and between the word line WL15 and the select gate line SGD. The hookup portion HPo includes the terraced portion of the select gate line SGS and the word lines WL0 to WL15.

The stepped area SA1 includes a terraced portion of each of the word lines WL11 to WL15. The stepped area SA2 includes a terraced portion of each of the word lines WL7 to WL10. The stepped area SA3 includes a terraced portion of each of the word lines WL3 to WL6. The stepped area SA4 includes a terraced portion of each of the word lines WL0 to WL2 and the select gate line SGS. These terraced portions are then aligned in the order of WL15, WL14, WL13, WL12, WL11, WL7, WL8, WL9, WL10, WL6, WL5, WL4, WL3, SGS, WL0, WL1, and WL2, along the X direction.

That is, in the stepped area SA1, a stepped structure formed by the terraced portions of the word lines WL11 to WL15 among the stacked interconnects has a structure ascending along the X direction and in a direction toward the memory area MA1. In other words, in the stepped area SA1, the stepped structure formed by the terraced portions of the word lines WL11 to WL15 among the stacked interconnects has a structure descending along the X direction and in a direction toward the memory area MA2.

In the stepped area SA2, a stepped structure formed by the terraced portions of the word lines WL7 to WL10 among the stacked interconnects has a structure ascending along the X direction and in a direction toward the memory area MA1. In other words, in the stepped area SA2, the stepped structure formed by the terraced portions of the word lines WL7 to WL10 among the stacked interconnects has a structure descending along the X direction and in a direction toward the memory area MA2.

In the stepped area SA3, a stepped structure formed by the terraced portions of the word lines WL3 to WL6 among the stacked interconnects has a structure ascending along the X direction and in a direction toward the memory area MA1. In other words, in the stepped area SA3, the stepped structure formed by the terraced portions of the word lines WL3 to WL6 among the stacked interconnects has a structure descending along the X direction and in a direction toward the memory area MA2.

In the stepped area SA4, a stepped structure formed by the terraced portions of the select gate line SGS and the word lines WL0 to WL2 among the stacked interconnects has a structure descending along the X direction and in a direction toward the memory area MA1. In other words, in the stepped area SA4, a stepped structure formed by the terraced portions of the select gate line SGS and the word lines WL0 to WL2 among the stacked interconnects has a structure ascending along the X direction and in a direction toward the memory area MA2.

An inclined portion IP1 is formed between the stepped structure provided in the stepped area SA1 and the stepped structure provided in the stepped area SA2. An inclined portion IP2 is formed between the stepped structure provided in the stepped area SA2 and the stepped structure provided in the stepped area SA3. An inclined portion IP3 is formed between the stepped structure provided in the stepped area SA3 and the stepped structure provided in the stepped area SA4. Each of the inclined portions IP1, IP2, and IP3 is formed by a side surface of multiple pairs of a conductive layer 23 and an insulating layer 32. In addition, the inclined portions IP1, IP2, and IP3 show that they are processed through the same manufacturing steps and each is processed in a batch.

For example, the area surrounded by the inclined portion IP1 includes stepped areas SA2, SA3, and SA4. The area surrounded by the inclined portion IP2 includes stepped areas SA3 and SA4. The area surrounded by the inclined portion IP3 includes stepped areas SA4. The area surrounded by the inclined portion IP2 is shifted to the block BLK0 side. The area surrounded by the inclined portion IP3 is shifted to the block BLK1 side. For example, the center line in the Y direction in the area surrounded by the inclined portion IP2 is included in a block BLKe, and the center line in the Y direction in the area surrounded by the inclined portion IP3 is included in a block BLKo. The center line in the Y direction in the area surrounded by the inclined portion IP2 and the center line in the Y direction in the area surrounded by the inclined portion IP3 are shifted at least in the Y direction.

A pair of the stepped areas SA1 and SA2 is formed based on a stadium-shaped stepped portion SS1. A pair of the stepped areas SA3 and SA4 is formed based on a stadium-shaped stepped portion SS2. The stadium-shaped stepped portion SS is formed by iterations of a slimming process and an etching process, which are described later, and is a pair of stepped structures facing each other in the X direction. At least a single inclined portion IP is provided between two stepped areas SA formed based on the same stadium-shaped stepped portion SS. The plurality of conductive layers 23 corresponding to the plurality of terraced portions included in the uppermost stepped area SA1 are not surrounded by the inclined portion IP.

In addition, in the hookup area HA, the memory cell array 10 includes a plurality of contacts CC. Within each block BLK, the contacts CC are respectively provided on the terraced portions of the select gate line SGS, word lines WL0 to WL15, and select gate lines SGD0 to SGD4. The contacts CC provided in the hookup portion HP and in an area of one of the blocks BLK are arranged in a straight line along the X direction, for example. These contacts are not necessarily arranged in a straight line, but may be arranged to be offset vertically from one another.

Each of the stacked interconnects coupled to the NAND string NS is electrically coupled to the row decoder module 15 via an associated contact CC. The contact CC and the row decoder module 15 are coupled via, for example, the contact area C4T. The contact CC may be coupled to the row decoder module 15 via a contact provided in a region outside of the memory cell array 10, or an area in which a contact passes through the stacked interconnects may be provided in the memory area MA. The contact CC within the hookup portion HP and the contact CC outside the hookup portion HP may be coupled to the row decoder module 15 via paths which differ from each other.

The stacked interconnects bypass the hookup portion HP, and are electrically coupled in an area opposite to a boundary of a set of two block areas in the Y direction, between the memory areas MA1 and MA2. Specifically, in the block BLK0, the stacked interconnects within the memory areas MA1 and MA2 are continuously provided between the slit SLTo adjacent to the block BLK0 and the hookup portion HP. On the other hand, in the block BLK1, the stacked interconnects within the memory areas MA1 and MA2 are continuously provided between the slit SLTo adjacent to the block BLK1 and the hookup portion HP.

The stacked interconnects provided in the hookup portion HPo have a level differences also in the Y direction. In such a portion, for example the contacts CC are not arranged, and the portion may be referred to as a “dummy stepped structure”. The dummy stepped structure is a structure collaterally formed in a manufacturing process of the semiconductor memory device 1. In this example, a width of the terraced portion in the Y direction in the stepped structure in the Y direction is approximately equal to that of the terraced portion in the X direction in the stepped structure in the X direction. For example, a Y-direction width of the terraced portion of the word line WL14 that is drawn in the Y direction is approximately equal to the X-direction width of the terraced portion of the word line WL14 that is drawn in the X direction.

For example, a portion corresponding to the block BLK0 (BLKe) and a portion corresponding to the block BLK1 (BLKo) in the hookup portion HPo have, for example, a structure symmetrical in the Y direction with reference to the slit SLTe. The structure in the hookup portion HPe is the same as that in the hookup portion HPo, for example. The structure in the hookup portion HPe may be a structure symmetric to the hookup portion HPo with respect to the X direction, or may be a different structure.

### Cross-Sectional Structure of Memory Cell Array 10 in Hookup Area HA

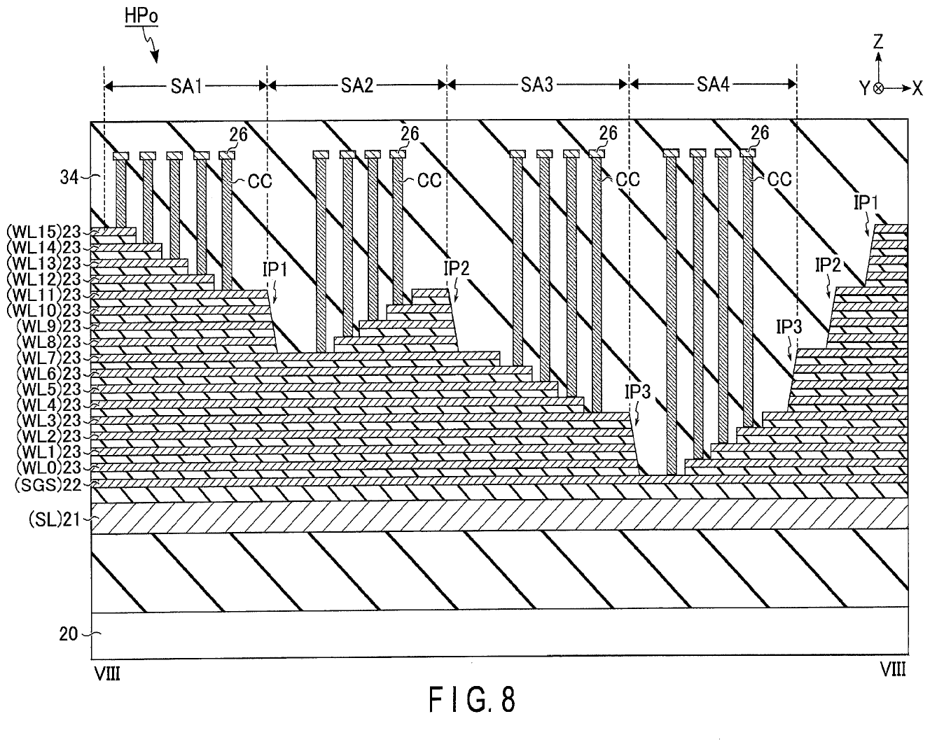

FIG. 8 is a cross-sectional view, taken along line VIII-VIII in FIG. 7, showing an example of a cross-sectional structure in a part of the hookup area HA of the memory cell array 10 included in the semiconductor memory device 1 according to the embodiment. FIG. 8 illustrates the stepped areas SA1 to SA4 in the hookup portion HPo. As shown in FIG. 8, in the hookup portion HPo, the edge portion of a conductive layer 23 corresponding to the word line WL is provided in a staircase pattern as described above with reference to FIG. 7, and the insulating layer 34 is formed thereabove.

The stepped structure provided in the stepped area SA1 and the stepped structure provided in the stepped area SA2 have, for example, a structure symmetrical in the X direction but are of different heights. The height of the stepped structure within the stepped area SA1 is greater than that of the stepped structure within the stepped area SA2. In this example, the stepped structure within the stepped area SA1 has a structure of a height greater than the stepped structure within the stepped area SA2 by four pairs of an insulating layer 32 and a conductive layer 23. The four-pair difference in height is made by the etching process by which the inclined portion IP1 is formed.

The stepped structure provided in the stepped area SA3 and the stepped structure provided in the stepped area SA4 have, for example, a structure symmetrical in the X direction but are of different heights. The height of the stepped structure within the stepped area SA3 is greater than that of the stepped structure within the stepped area SA4. In this example, the stepped structure within the stepped area SA3 has a structure of a height greater than the stepped structure within the stepped area SA4 by four pairs of an insulating layer 32 and a conductive layer 23. The four-pair difference in height is made by the etching process by which the inclined portion IP3 is formed.

The stepped structures provided in the stepped areas SA1 and SA2 and those in the stepped areas SA3 and SA4 have the same structure except for, for example, their heights. The height of the stepped structures within the stepped areas SA1 and SA2 is greater than that of the stepped structures within the stepped areas SA3 and SA4. In this example, the stepped structures within the stepped areas SA1 and SA2 have a structure of a height greater than the stepped structure within the stepped areas SA3 and SA4 by eight pairs of an insulating layer 32 and a conductive layer 23. The eight-pair difference in height by is made by the etching process by which the inclined portion IP2 is formed and the etching process by which the inclined portion IP3 is formed.

In addition, in the hookup area HA, the memory cell array 10 includes a plurality of conductive layers 26. The contacts CC are provided on the respective terraced portions of the word lines WL0 to WL15 and the select gate line SGS. A single conductive layer 26 is provided on each contact CC. The conductive layers 22 and 23 and the conductive layer 26 associated therewith are thereby electrically coupled via the contact CC. The conductive layers 26 are included in, for example, a layer having the same height as that of the conductive layer 25.

The height of each of the inclined portions IP1, IP2, and IP3 may vary in accordance with their locations. For example, the height of the inclined portion IP1 located between the stepped area SA1 and SA2 is lower than that of the inclined portion IP1 located at the edge portion of the hookup portion HPo. The height of the inclined portion IP3 located between the stepped area SA3 and SA4 is lower than that of the inclined portion IP3 located at the edge portion of the hookup portion HPo. The variation in height according to the locations of the inclined portions IP may be caused by overlapping of the etching areas in the manufacturing steps (which will be described later).

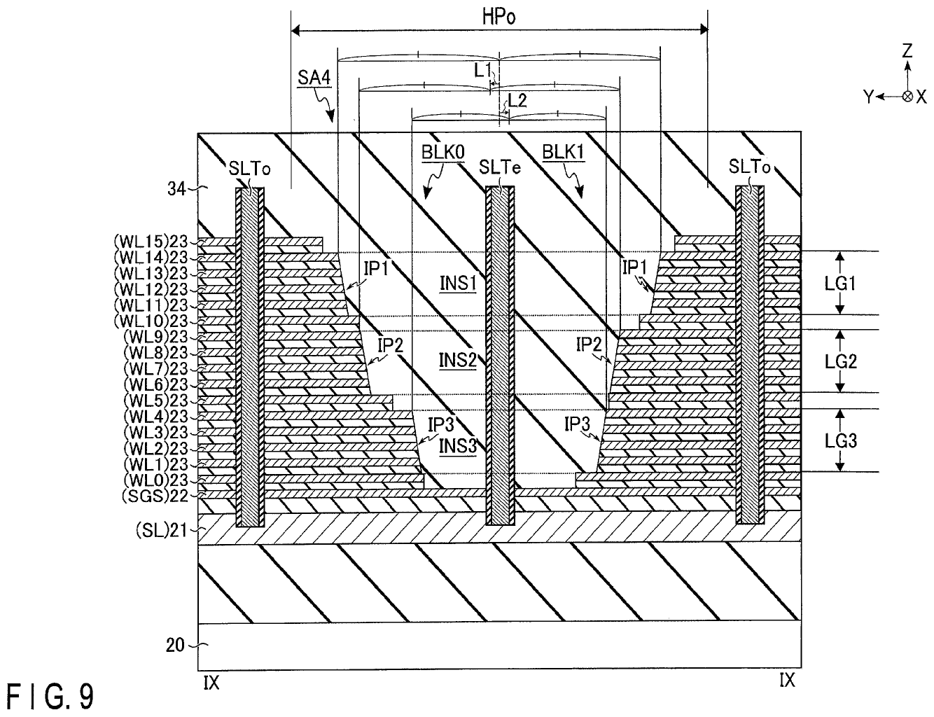

FIG. 9 is a cross-sectional view, taken along line IX-IX in FIG. 7, showing an example of a cross-sectional structure in a part of the hookup area HA of the memory cell array 10 included in the semiconductor memory device 1 according to the embodiment. FIG. 9 shows an area that includes the stepped area SA4. As shown in FIG. 9, in the stepped area SA4, the memory cell array 10 has a stack structure processed in a concave shape as a result of removal of parts of the stacked interconnect, and the concave parts after the removal is filled with an insulating layer 34. The slit SLTe between the blocks BLK0 and BLK1 divides the conductive layer 22 and insulating layer 34 in the hookup portion HPo.

The block BLK0 includes the inclined portions IP1 to IP3 that each ascend the positive direction of the Y direction (one side), and the block BLK1 includes the inclined portions IP1 to IP3 that each ascend the negative direction of the Y direction (the other side). In other words, in the area corresponding to the block BLK0 (BLKe), the stacked conductive layers 23 have a plurality of inclined portions IP ascending toward the slit SLTo to which the block BLK0 is adjacent. Similarly, in an area corresponding to the block BLK1 (BLKo), the stacked conductive layers 23 have a plurality of inclined portions IP ascending toward the slit SLTo to which the block BLK1 is adjacent.

Then, the arrangement of the plurality of inclined portions IP in the area corresponding to the block BLK0 and those in the area corresponding to the block BLK1 are provided asymmetrically. Hereinafter, this layout will be described, using the upper edge portion of each inclined portion IP as a reference. In the following, the layer groups of conductive layers 23 respectively including the inclined portions IP1, IP2, and IP3 in the stepped area SA4 will be referred to as “LG1”, “LG2”, and “LG3”, respectively.

The insulating layer 34 includes a first portion INS1 provided at the height of the layer group LG1, a second portion INS2 provided at the height of the layer group LG2, and a third portion INS3 provided at the height of the layer group LG3. The first portion INS1 of the insulating layer 34 is sandwiched between the conductive layers 23 included in the layer group LG1 in the Y direction. The second portion INS2 of the insulating layer 34 is sandwiched between the conductive layers 23 included in the layer group LG2 in the Y direction. The third portion INS3 of the insulating layer 34 is sandwiched between the conductive layers 23 included in the layer group LG3 in the Y direction. The first portion INS1, the second portion INS2, and the third portion INS3 of the insulating layer 34 are divided by the slit SLTe. The side surfaces of the conductive layers 23 included in the layer group LG1 are aligned in the part which is in contact with the first portion INS1 of the insulating layer 34. The side surfaces of the conductive layers 23 included in the layer group LG2 are aligned in the part which contacts the second portion INS2 of the insulating layer 34. The side surfaces of the conductive layers 23 included in the layer group LG3 are aligned in the part which contacts the third portion INS3 of the insulating layer 34.

The center line of the inclined portions IP2 provided in the block BLK0 and the inclined portions IP2 in the block BLK1 is shifted to the positive side of the Y direction with respect to the center line of the inclined portions IP1 provided in the block BLK0 and the inclined portions IP1 in the block BLK1. The center line of the inclined portions IP3 provided in the block BLK0 and the inclined portions IP3 in the block BLK1 is shifted to the negative side of the Y direction with respect to the center line of the inclined portions IP1 provided in the block BLK0 and the inclined portions IP1 in the block BLK1. In FIG. 9, an amount of shift of the center line of the neighboring inclined portions IP2 in the Y direction in the hookup portion HPo is indicated as “L1”, and an amount of shift of the center line of the neighboring inclined portions IP3 in the Y direction in the hookup portion HPo is indicated as “L2”.

In the semiconductor memory device 1 according to the embodiment, the stepped structure formed in the hookup portion HP may be other structures. The stepped structure of the hookup portion HP may be made from three or more stadium-shaped stepped portions arranged in the X direction. Alternately, a plurality of stadium-shaped stepped portions having lengths differing in the X direction may be stacked. The height from the bottom to the top of each of the inclined portions IP may be the same or different. Similarly, the height from the bottom to the top of each of the layer groups LG1 to LG3 may be the same or different. Four or more inclined portions IP may be formed in the same hookup portion HP. It suffices that the semiconductor memory device 1 according to the embodiment has at least a set of inclined portions IP whose center line is shifted to the positive side of the Y direction and a set of inclined portions IP whose center line is shifted to the negative side of the Y direction, other than the inclined portions IP corresponding to the layer group LG1 of the topmost layers. Different types of inclined portions IP may be provided in a stacked manner. The position of each of the inclined portions IP may be specified in accordance with the height of the layer group LG.

### [2] Manufacturing Method

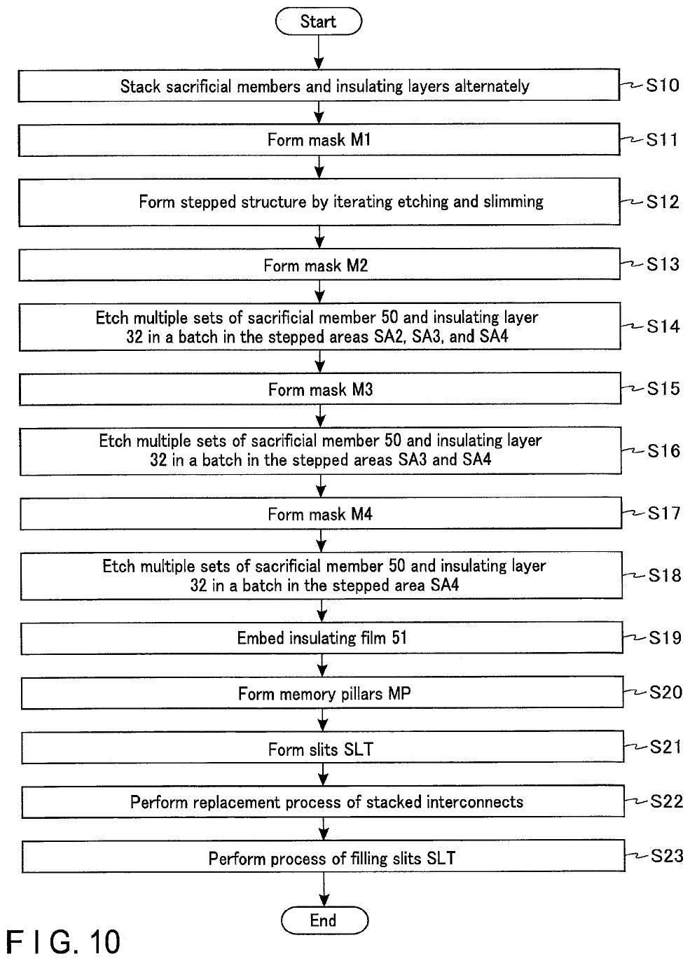

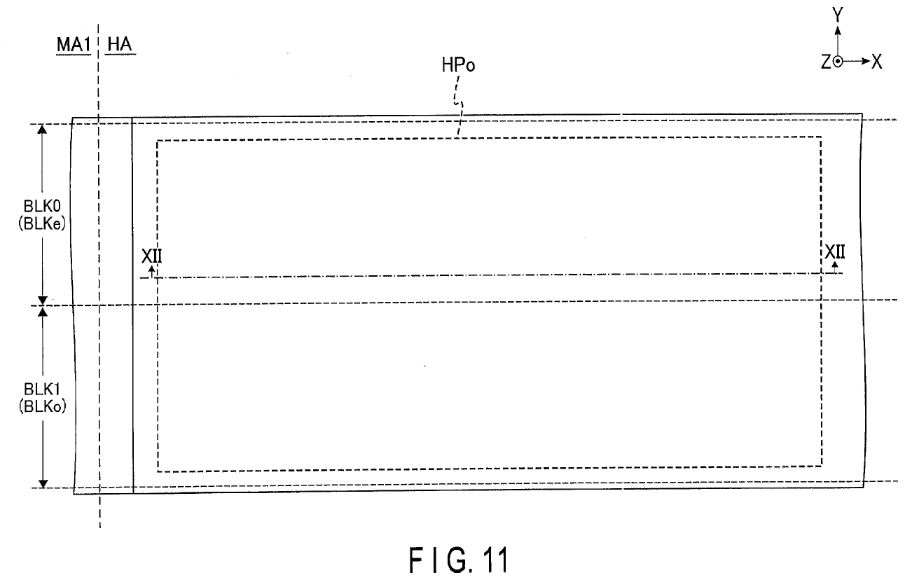

FIG. 10 is a flowchart showing an example of the method for manufacturing the semiconductor memory device 1 according to the embodiment. FIGS. 11 to 30 are either a plan view or a cross-sectional view showing an example of a structure of the memory cell array included in the semiconductor memory device 1 in the course of the manufacturing process according to the embodiment. The plan view used to describe the manufacturing method shows the same area as that shown in FIG. 7. The cross-sectional views used for explanation of the manufacturing method show the same area as that of FIG. 8 or 9. In the following, an example of a manufacturing process relating to formation of the stacked interconnects of the memory cell array 10 in the semiconductor memory device 1 according to the embodiment will be described with reference to FIG. 10 as needed. As shown in FIG. 10, in the manufacturing process of the semiconductor memory device 1 according to the embodiment, steps S10 to S23 are sequentially performed.

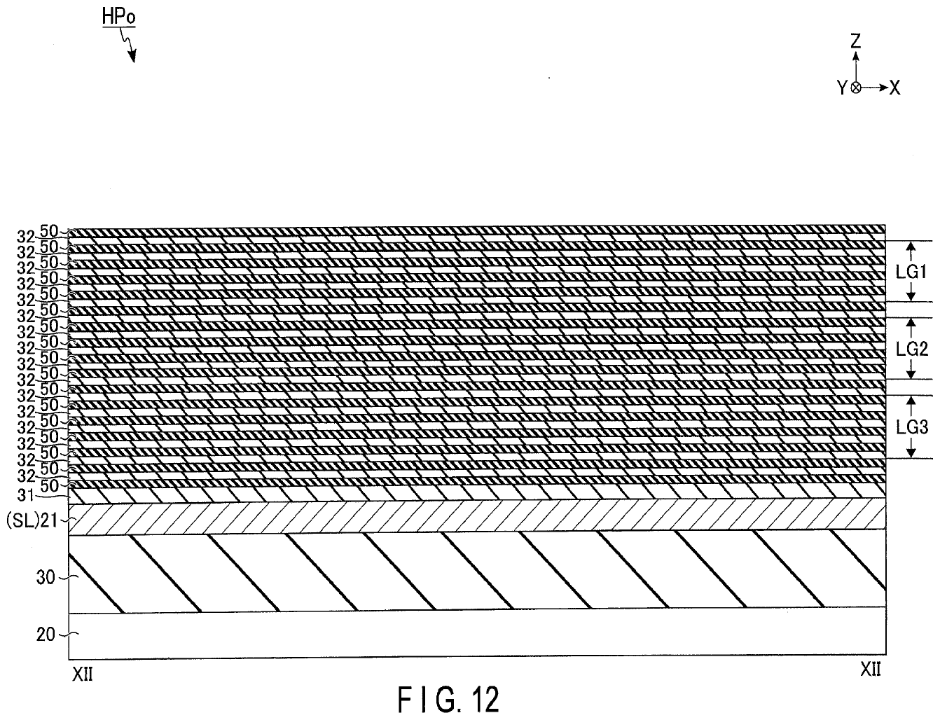

In the process of step S10, the sacrificial members and the insulating layers are alternately stacked. Briefly, the insulating layer 30 including circuitry (not shown) corresponding to the row decoder module 15, etc. is formed on the semiconductor substrate 20. Then, the conductive layer 21 and the insulating layer 31 are formed on the insulating layer 30 in this order. On the insulating layer 31, the sacrificial members and the insulating layers are alternately stacked. Then, a part of each of the insulating layers and a part of each of the sacrificial members are removed in the hookup area HA. As shown in FIG. 11, a step is formed by at least a single layer of the sacrificial member in the vicinity of the boundary between the hookup area HA and the memory area MA1. Sacrificial members 50, shown in FIG. 12, are associated with the select gate line SGS or one of the word lines WL.

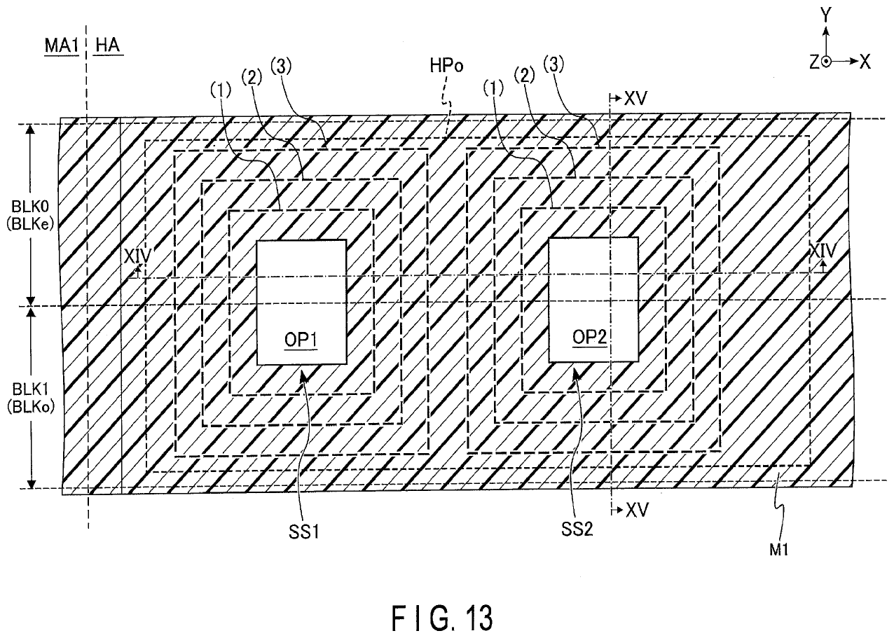

In the process of step S11, a mask M1 is formed as shown in FIG. 13. The mask M1 is formed by, for example, lithography and includes opening portions OP1 and OP2. The opening portion OP1 includes the center portion of the area in which the stadium-shaped stepped portion SS1 is formed and, in this example, corresponds to the area in which the terraced portion of each of the word lines WL11 and WL7 is formed. The opening portion OP2 includes the center portion of the area in which the stadium-shaped stepped portion SS2 is formed and, in this example, corresponds to the area in which the terraced portions of the word lines WL3 and the select gate line SGS are formed.

In the process in step S12, the stepped structure is formed by iterating an etching process and a slimming process. Specifically, anisotropic etching is performed using the mask M1, and a single layer of a sacrificial member 50 is thereby removed. The mask M1 is shrunk by isotropic etching, and the opening portions OP1 and OP2 isotopically expand as shown in FIG. 13(1) (a slimming process). Subsequently, anisotropic etching is performed using the mask M1, and a single layer of a sacrificial member 50 is thereby removed in the opening portions OP1 and OP2. The mask M1 is shrunk by isotropic etching, and the opening portions OP1 and OP2 isotopically expand as shown in FIG. 13(2). Subsequently, anisotropic etching is performed using the mask M1, and a single layer of a sacrificial member 50 is thereby removed in the opening portions OP1 and OP2. The mask M1 is shrunk by isotropic etching, and the opening portions OP1 and OP2 isotopically expand as shown in FIG. 13(3). Subsequently, anisotropic etching is performed using the mask M1, and the layer of a sacrificial member 50 is thereby removed in the opening portions OP1 and OP2.

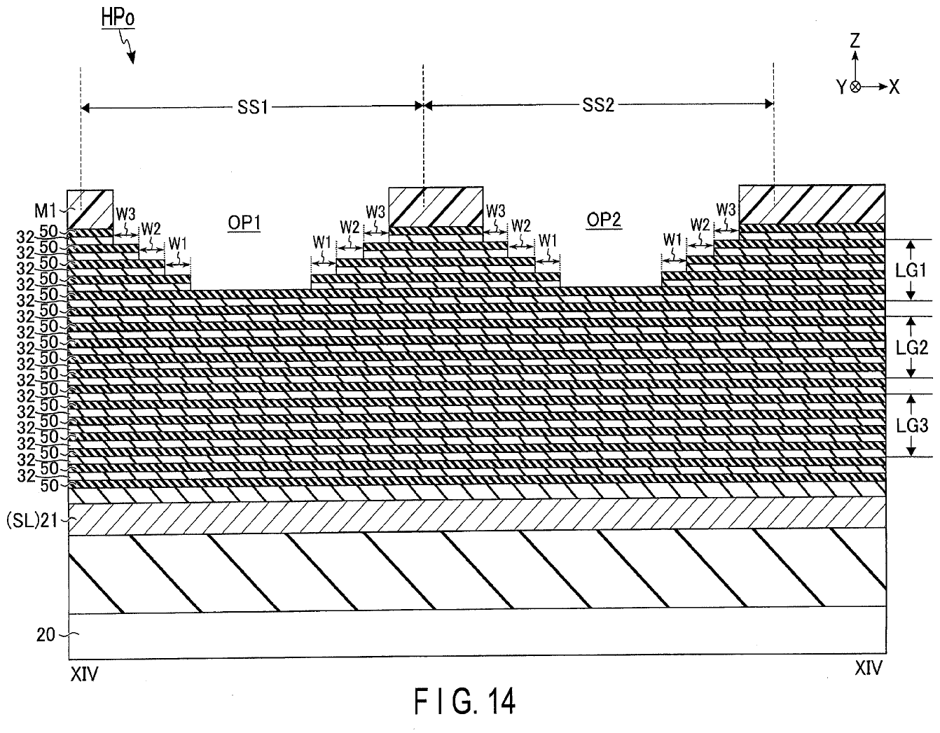

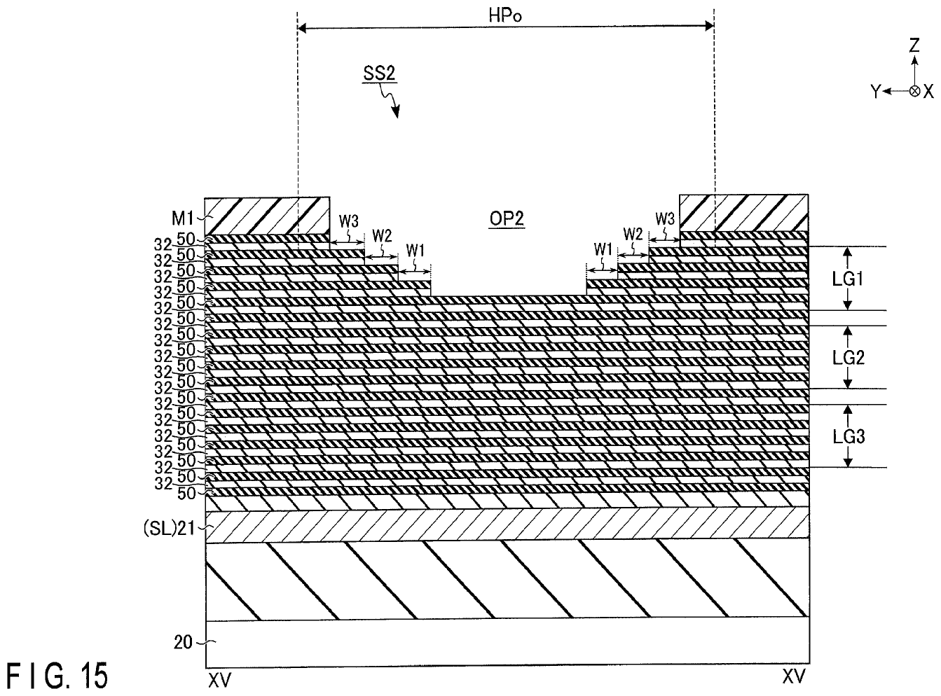

Thus, the stadium-shaped stepped portions SS1 and SS2 each having three steps in each of the X direction and the Y direction are formed, as shown in FIGS. 14 and 15. The width W1 of the terraced portion formed in the first step is approximately the same between the X direction and the Y direction. The width W2 of the terraced portion formed in the second step is approximately the same between the X direction and the Y direction. The width W3 of the terraced portion formed in the third step is approximately the same between the X direction and the Y direction. It is desirable for the widths W1 to W3 to be equal; however, they may be different. After completing the process in step 512, the mask M1 is removed.

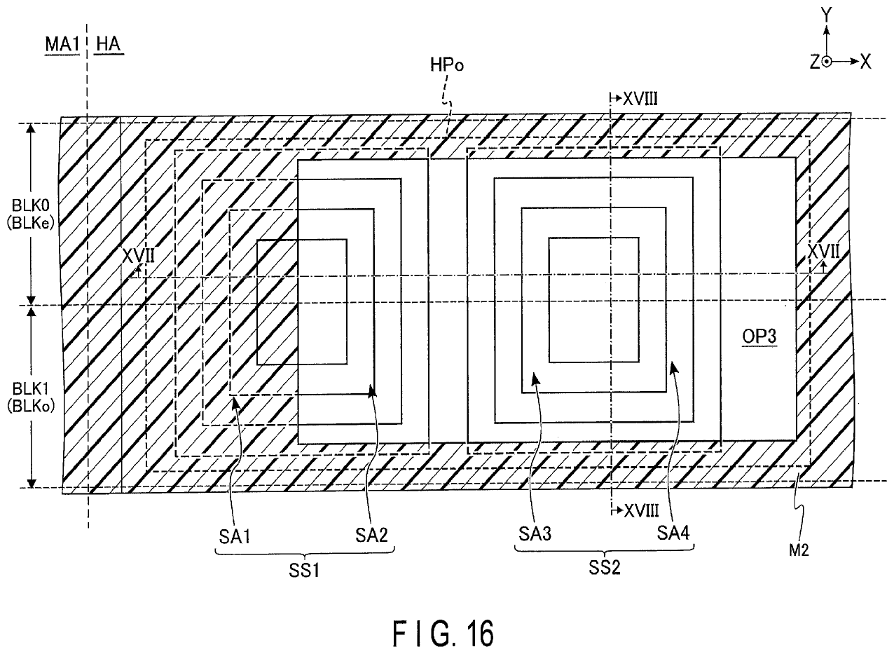

In the process of step S13, a mask M2 is formed as shown in FIG. 16. The mask M2 is formed by, for example, lithography and includes an opening portion OP3. The opening portion OP3 includes an area in which the stepped areas SA2, SA3, and SA4 are formed.

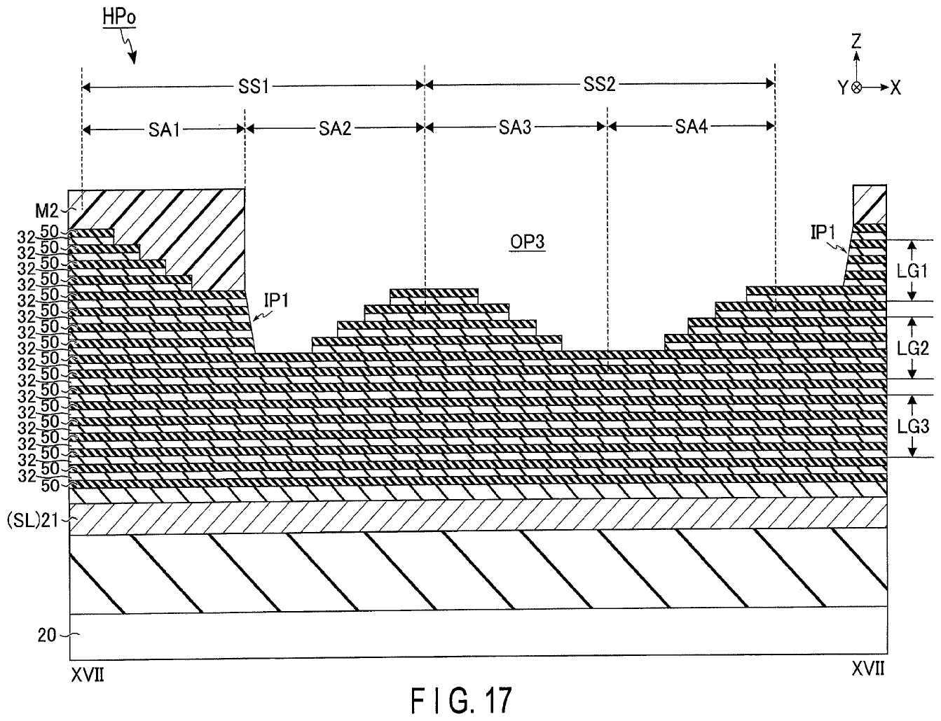

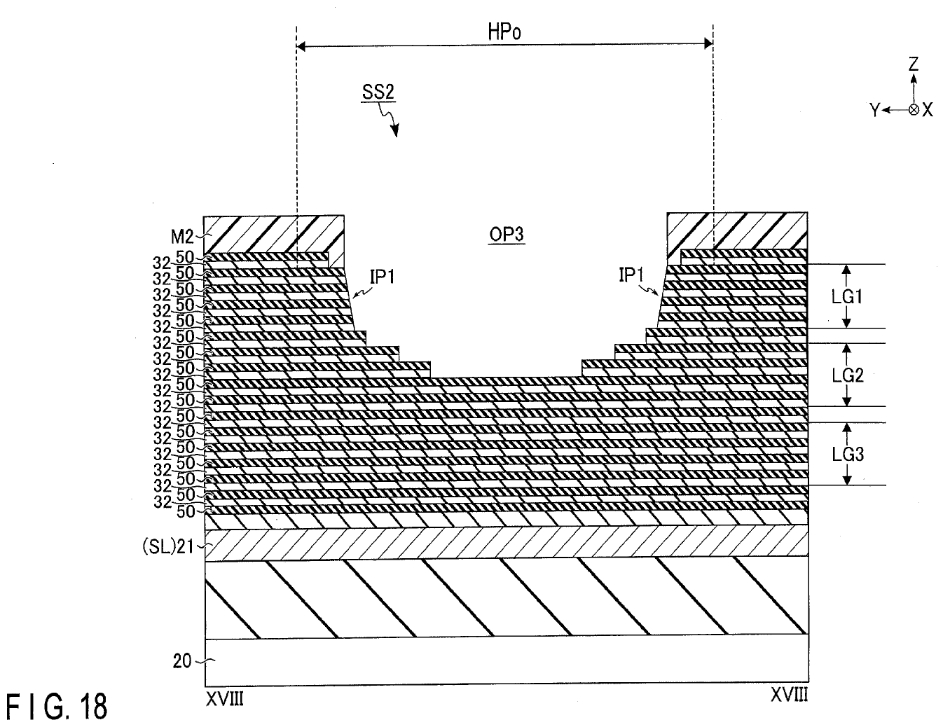

In the process of step S14, multiple pairs of a sacrificial member 50 and an insulating layer 32 of the stepped areas SA2, SA3, and SA4 are etched in a batch. Specifically, the anisotropic etching is performed using the mask M2, and as shown in FIG. 17, four pairs of a sacrificial member 50 and an insulating layer 32 are thereby removed in the opening portion OP3, and the inclined portion IP1 is thereby formed. In this process, the height including the plurality of sacrificial members 50 included at least in the first layer group LG1 is etched. As a result, in the stepped area SA2, the terraced portion is formed at the height of each of the word lines WL7 to WL10. As shown in FIG. 18, the inclined portions IP1 facing each other in the Y direction are formed in the cross section along the Y direction including the stadium-shaped stepped portion SS2. After completing the process in step S14, the mask M2 is removed.

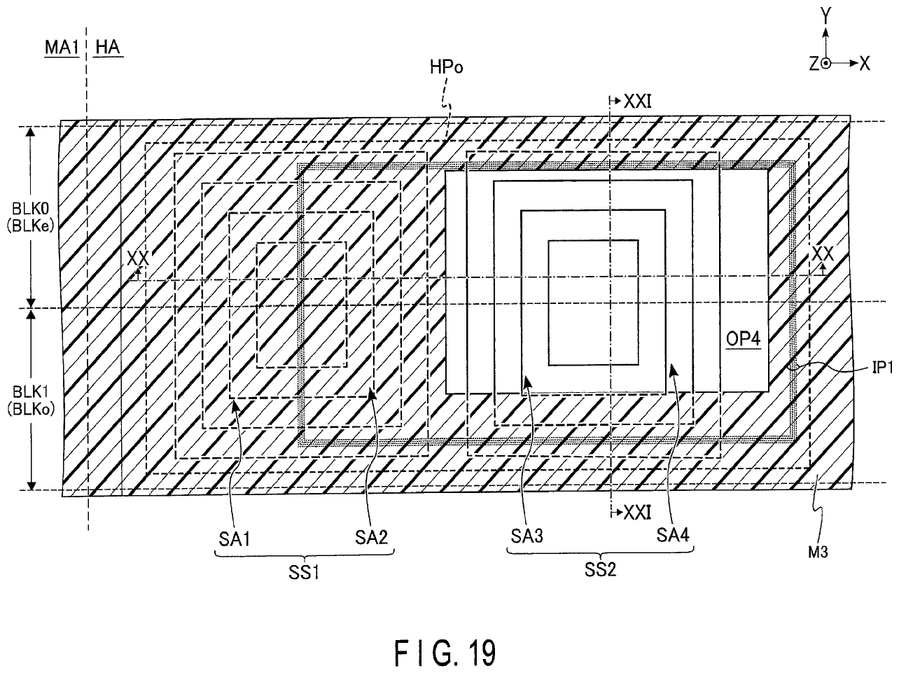

In the process of step S15, a mask M3 is formed as shown in FIG. 19. The mask M3 is formed by, for example, lithography and includes an opening portion OP4. The opening portion OP4 includes an area in which the stepped areas SA3 and SA4 are formed. The opening portion OP4 is provided in such a manner that the center line thereof in the Y direction is shifted to the positive side of the Y direction with respect to the center line of the stadium-shaped stepped portion SS2 in the Y direction. In other words, by the lithography performed at the time of forming a mask M3, an overlay process is performed in such a manner that the center line of the opening portion OP4 is shifted to the positive side of the Y direction with respect to the center line of the stadium-shaped stepped portion SS2.

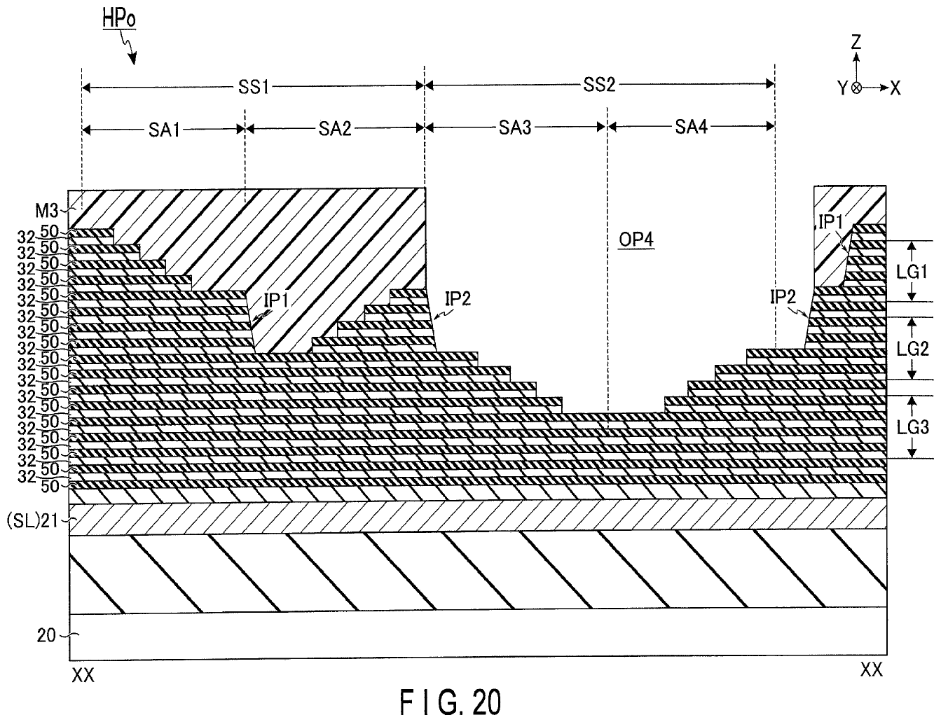

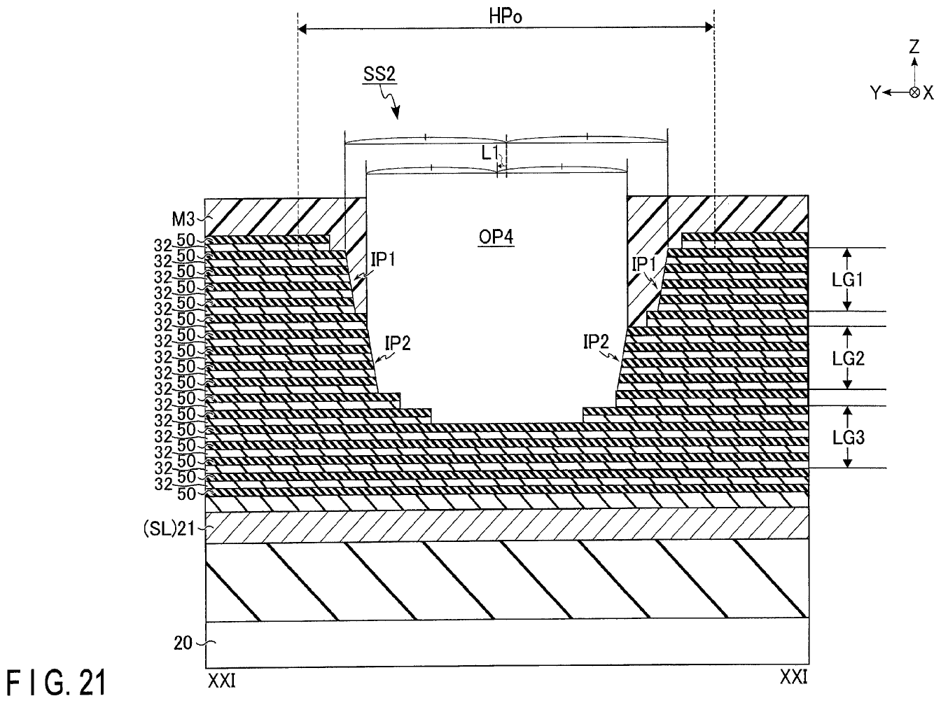

In the process of step S16, multiple pairs of a sacrificial member 50 and an insulating layer 32 of the stepped areas SA3 and SA4 are etched in a batch. Specifically, the anisotropic etching is performed using the mask M3, and as shown in FIG. 20, four pairs of a sacrificial member 50 and an insulating layer 32 are thereby removed in the opening portion OP4, and the inclined portion IP2 is thereby formed. In this process, parts of the plurality of the sacrificial members 50 included in the second layer group LG2, which is lower than the first layer group LG1, are etched in a batch. As a result, in the stepped area SA3, the terraced portion is formed at the height of each of the word lines WL3 to WL6. As shown in FIG. 21, the inclined portions IP2 facing each other in the Y direction are formed in the cross section along the Y direction including the stadium-shaped stepped portion SS2. If the Y-direction center line of the inclined portions IP1 facing each other in the Y direction is used as a reference, an amount of shift L1 of the center line of the inclined portion IP2 adjacent to the inclined portion IP1 in the Y direction within the hookup portion HPo is a positive value. After completing the process in step S16, the mask M3 is removed.

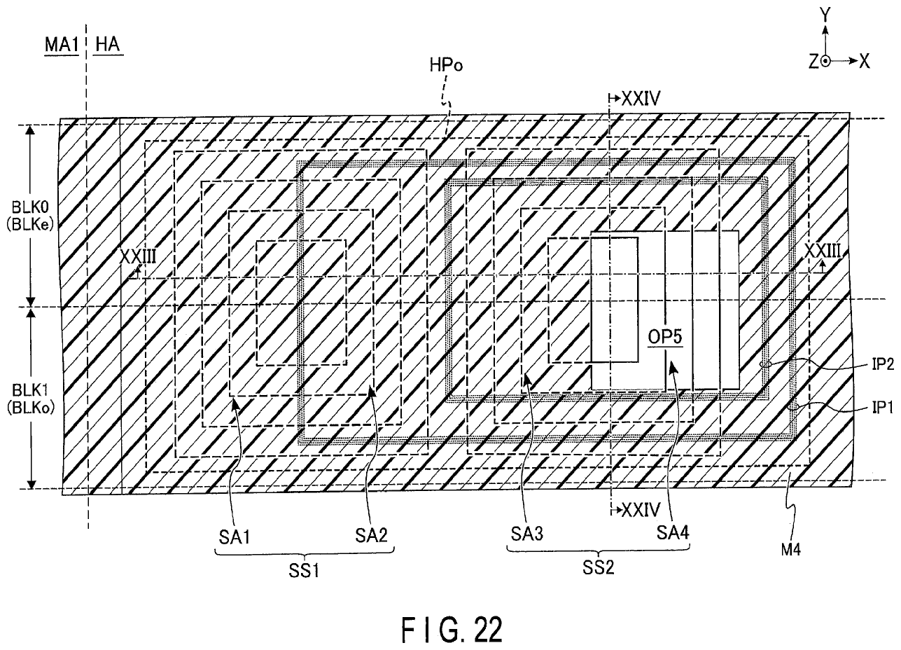

In the process of step S17, a mask M4 is formed as shown in FIG. 22. The mask M4 is formed by, for example, lithography, and includes an opening portion OP5. The opening portion OP5 includes an area in which the stepped area SA4 is formed. The opening portion OP5 is provided in such a manner that the center line thereof in the Y direction is shifted to the negative side of the Y direction with respect to the center line of the stadium-shaped stepped portion SS2 in the Y direction. In other words, by the lithography performed at the time of forming a mask M4, an overlay process is performed in such a manner that the center line of the opening portion OP5 is shifted to the negative side of the Y direction with respect to the center line of the stadium-shaped stepped portion SS2.

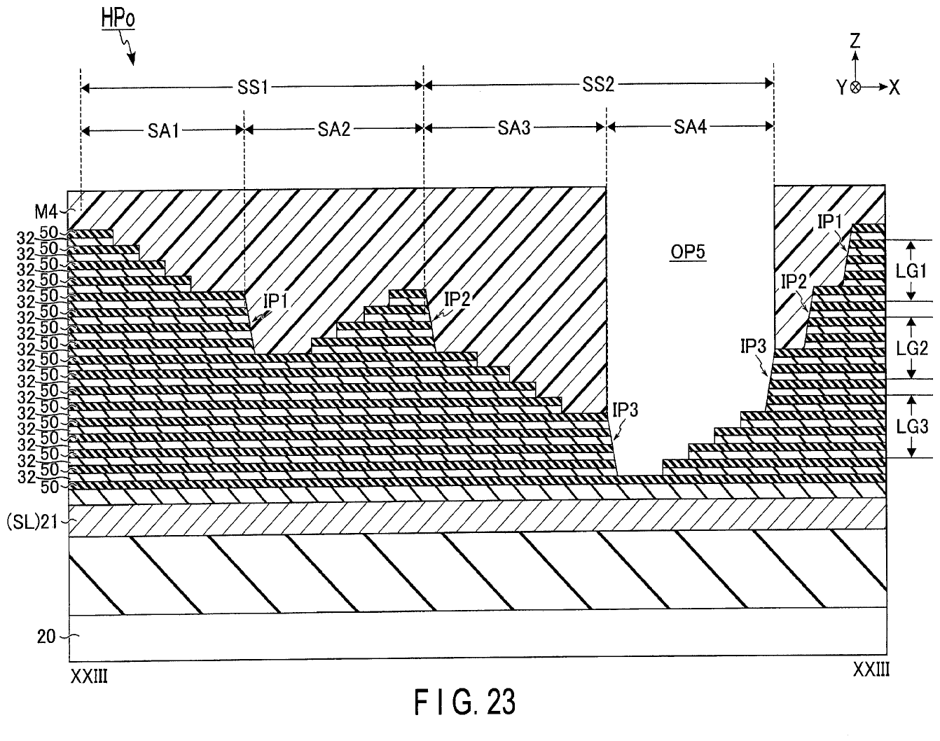

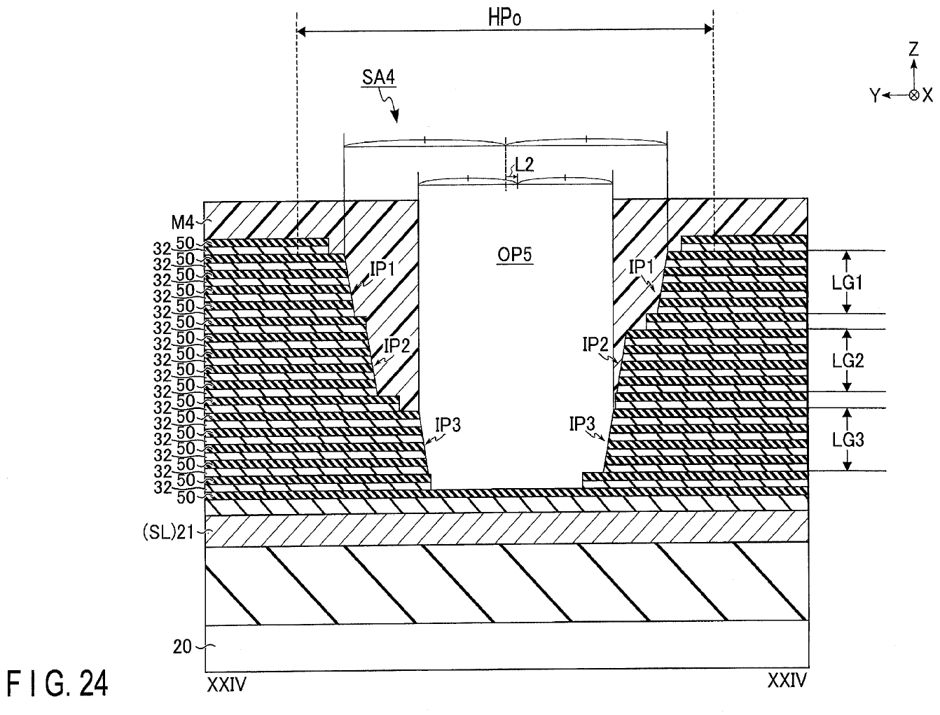

In the process of step S18, multiple pairs of a sacrificial member 50 and an insulating layer 32 of the stepped area SA4 are etched in a batch. Specifically, the anisotropic etching is performed using the mask M4, and as shown in FIG. 23, four pairs of a sacrificial member 50 and an insulating layer 32 are thereby removed in the opening portion OP5, and the inclined portion IP3 is thereby formed. In this process, parts of the plurality of the sacrificial members 50 included in the third layer group LG3, which is lower than the second layer group LG2, are etched in a batch. As a result, in the stepped area SA4, the terraced portion is formed at the height of each of the word lines WL0 to WL2 and the select gate line SGS. As shown in FIG. 24, the inclined portions IP3 facing each other in the Y direction are formed in the cross section along the Y direction including the stepped area SA4 in the stadium-shaped stepped portion SS2. If the Y-direction center line of the inclined portions IP1 facing each other in the Y direction is used as a reference, an amount of shift L2 of the center line of the inclined portion IP3 adjacent to the inclined portion IP1 in the Y direction within the hookup portion HPo is a negative value. After completing the process in step S18, the mask M4 is removed.

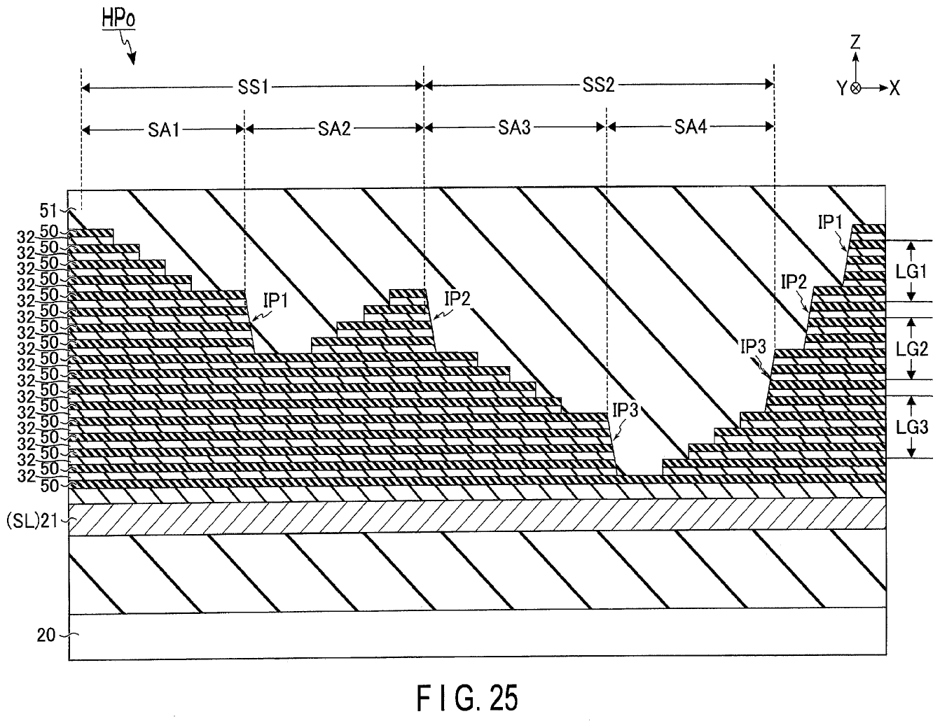

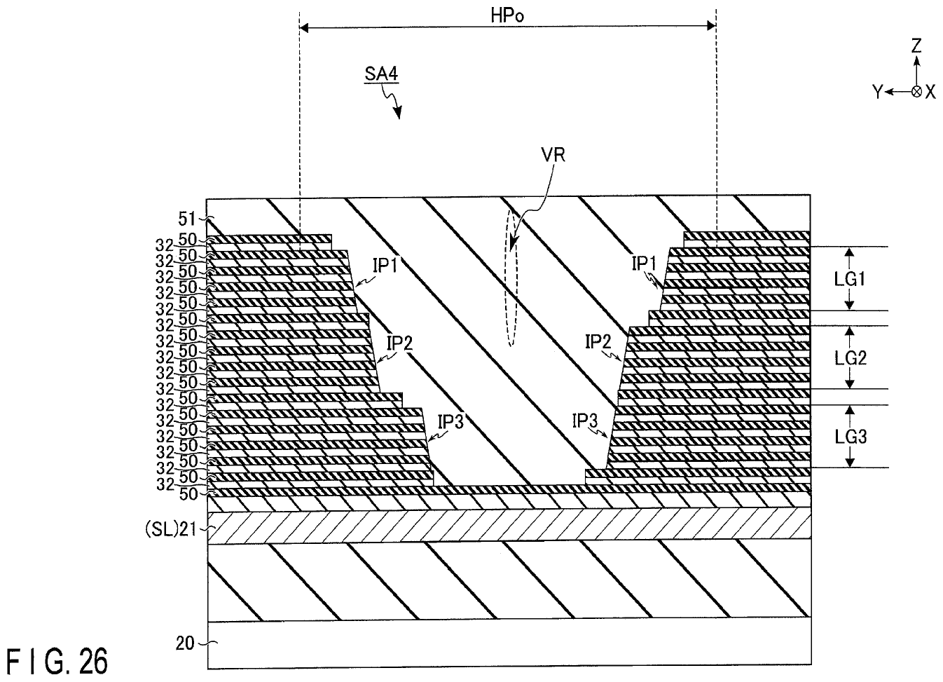

In the process of step S19, an insulating film 51 is formed on the plurality of terraced portions of the plurality of sacrificial members 50 provided in the hookup portion HP, as shown in FIG. 25. In other words, the steps formed in the hookup portion HP of the hookup area HA are embedded by the insulating film 51. Then, the top surface of the insulating film 51 is planarized by, for example, chemical mechanical polishing (CMP). In this step, the insulating film 51 is formed by chemical vapor deposition (CVD), for example. In the insulating film 51 thereby formed, a seam or a void may be formed in the area where the stacked interconnects are processed in a concave shape in the hookup portion HP. For example, as shown in FIG. 26, in the stepped area SA4, a void may be formed in the area VR between the inclined portions IP facing each other in the Y direction.

In the process of step S20, a plurality of memory pillars MP are formed. Briefly, a mask in which areas corresponding to the memory pillars MP are opened is first formed. Then, a plurality of memory holes are formed by anisotropic etching using the mask. After that, the block insulating film 45, the insulating film 44, and the tunnel insulating film 43 are sequentially formed on side surfaces and bottom surfaces of the memory holes. Then, a part of the block insulating film 45, the insulating film 44, and the tunnel insulating film 43 provided at a bottom portion of each memory hole is removed, and the semiconductor layer 41 and the core member 40 are formed in the memory hole. Thereafter, a part of the core member 40 provided at an upper part of the memory hole is removed, and the semiconductor layer 41 is formed in that part. Thereby, a plurality of memory pillars MP are formed. Thereafter, the insulating layer 52 is formed on the insulating film 51. The insulating layer 52 protects the upper portions of the memory pillars MP. The insulating film 51 and the insulating layer 52 are included in the insulating layer 34 shown in FIG. 8.

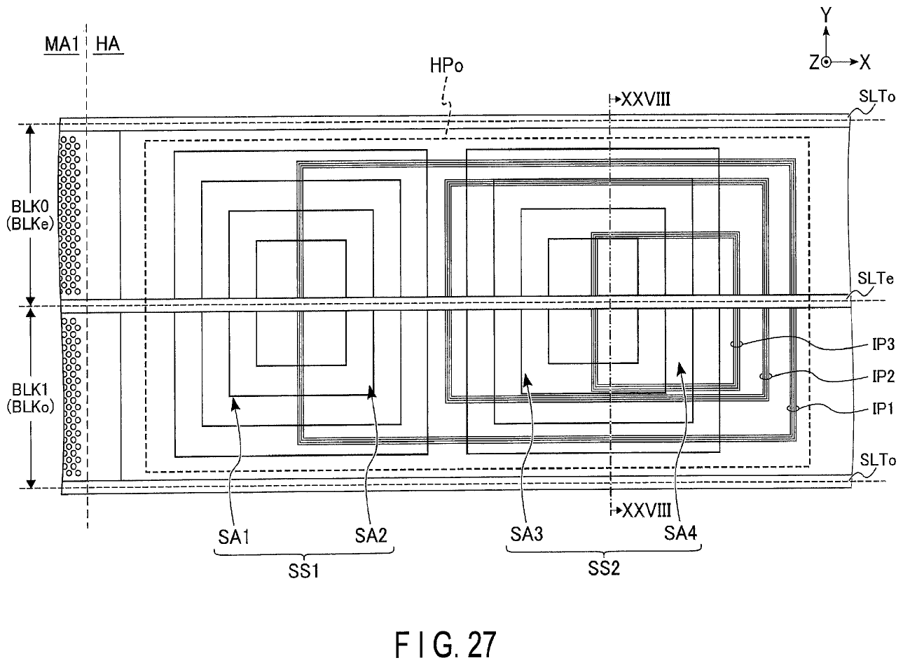

In the process of step S21, as shown in FIG. 27, a plurality of slits SLT are formed. Specifically, a mask in which areas corresponding to the slits SLT are opened is formed by photolithography, etc. Thereafter, by anisotropic etching using the mask, for example, the slits SLT that divide the plurality of the sacrificial members 50 are formed. In the area outside of the hookup portion HPo, the slits SLT also divide sacrificial members corresponding to the select gate line SGD.

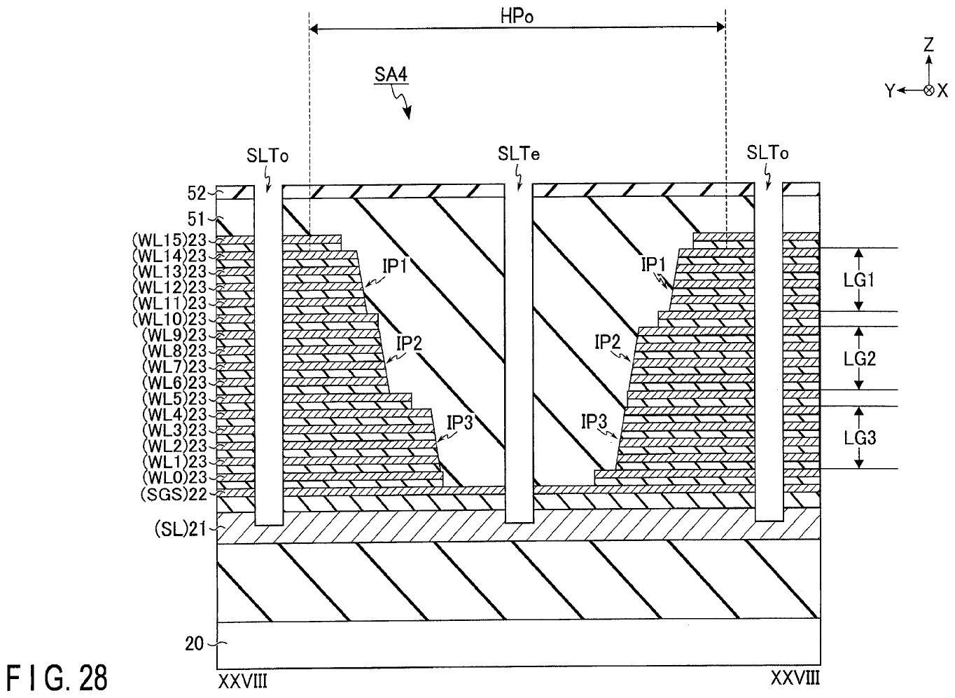

In the process of step S22, a replacement process of the stacked interconnects is performed, and a stacked interconnect structure is formed as shown in FIG. 28. Specifically, first the plurality of sacrificial members 50 are selectively removed via the slits SLT by wet etching using thermal phosphoric acid, etc. The structure after the sacrificial members 50 are removed is maintained by a plurality of memory pillars MP or support pillars, illustration of which is omitted, etc. Thereafter, a conductor is embedded in the spaces from which the sacrificial members 50 have been removed, via the slits SLT. To form the conductor in this step, CVD is used for example.

After that, the conductor formed inside the slits SLT is removed by an etch-back process, and the conductor formed in adjacent interconnect layers is separated. Thereby, the conductive layer 22 which functions as a select gate line SGS, the conductive layers 23 which respectively function as word lines WL0 to WL15, and the conductive layer 24 which functions as a select gate line SGD, are respectively formed. The conductive layers 22 to 24 formed in this step may include a barrier metal. In the formation of the conductor after the removal of the sacrificial members 50, tungsten is formed after, for example, a titanium nitride film is formed as a barrier metal.

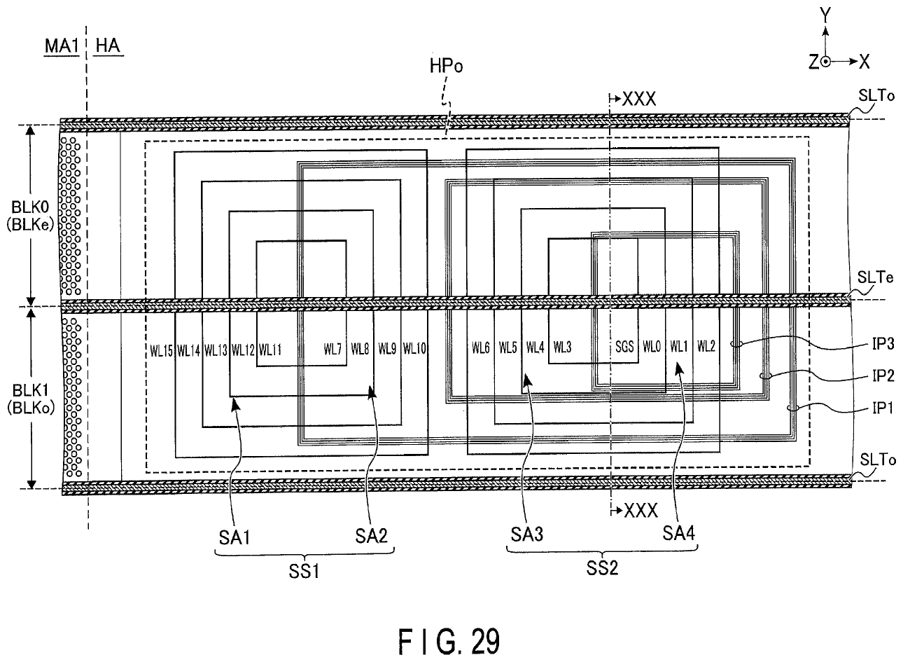

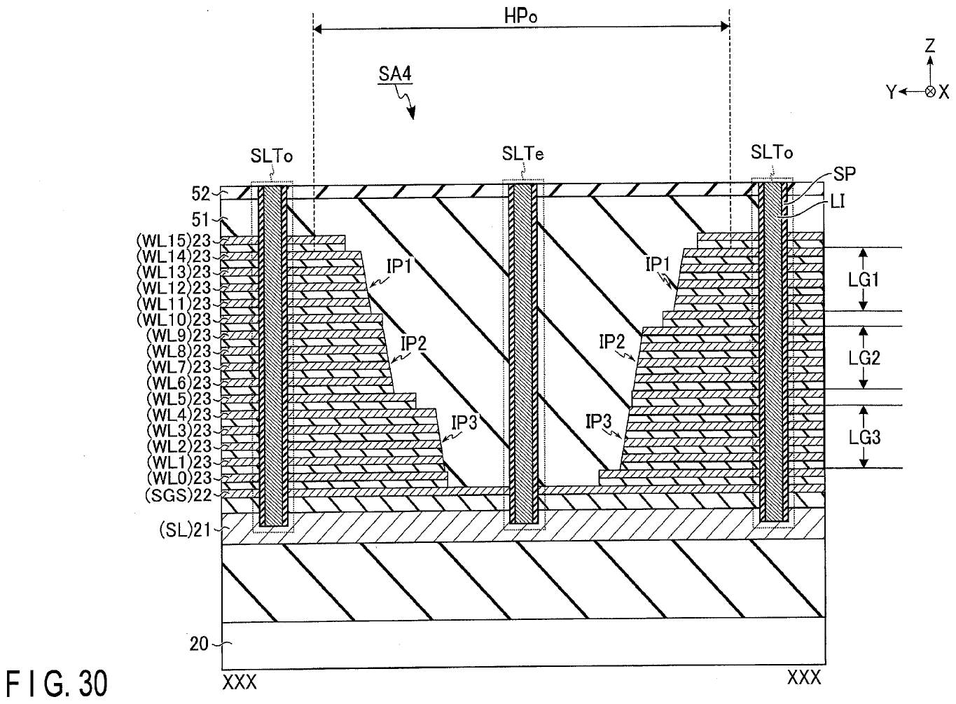

In the process of step S23, a process of filling the slits SLT is performed as shown in FIGS. 29 and 30. Specifically, an insulating film (spacer SP) is formed so as to cover a side surface and a bottom surface of each slit SLT. Thereafter, a portion of the spacer SP provided at a bottom portion of the slit SLT is removed, and a portion of the conductive layer 21 is exposed at the bottom portion of the slit SLT. Thereafter, a conductor (contact LI) is formed in the slit SLT, and the conductor formed outside the slit SLT is removed by, for example, CMP. After this, a plurality of concave portions are formed between slits SLT adjacent to each other in the Y direction so as to be in parallel to the slits SLT, and an insulating film is embedded in each concave portion so as to form a slit SHE that divides the conductive layer 24 in the Y direction.

By the manufacturing process of the semiconductor memory device 1 according to the embodiment described above, a stepped structure for connecting the stacked interconnects in the memory cell array 10 to the contacts is formed. The above-described manufacturing process is merely an example, and the manufacturing process is not limited thereto. For example, other process may be inserted between the manufacturing steps, and some of the steps may be omitted or integrated. The manufacturing steps may be interchanged where possible. For example, the step of forming memory pillars MP and the step of forming a stepped structure of stacked interconnects may be interchanged. The batch etching of multiple pairs of an insulating layer 32 and a sacrificial member 50, as performed in steps S14, S16, and S18, may be referred to as “multiple-stage processing”.

### [3] Advantageous Effects

The semiconductor memory device 1 according to the above-described embodiment is capable of improving the yield of the semiconductor memory device 1. In the following, details of advantageous effects in the semiconductor memory device 1 according to the embodiment will be described using a comparative example.

A semiconductor memory device including three-dimensionally stacked memory cells includes, for example, stacked interconnects including a word line WL, and a memory pillar MP which penetrates the stacked interconnects and whose intersection with the word line WL functions as the memory cell. The stacked interconnects have, for example, a portion provided in a stepped shape (hereinafter, referred to as a “step part”). The row decoder module 15 applies a voltage to the word line WL, etc. through a contact coupled to the step part of the stacked interconnects. Furthermore, as a structure for cutting back a chip area size of a semiconductor memory device, a structure in which the memory cell array 10 and a circuit such as the row decoder module 15 are stacked in a direction vertical to the surface of a substrate is known.

In the case where the row decoder module 15 is fanned below the memory cell array 10, the stepped portion of the stacked interconnects is arranged in, for example, a middle area of the memory cell array 10 in the X direction. If a stepped portion of the stacked interconnects is formed in such an arrangement, it is preferable that the number of manufacturing steps be reduced through utilizing multiple-stage processing so as to suppress manufacturing cost. The number of times of performing the multiple-stage processing tends to increase along with the increase in the number of stacked word line WL layers.

However, if the number of times of performing the multiple-stage processing is increased, there is a possibility that a void, which is formed in an insulating film embedded in an area on which the multiple-stage processing is performed several times, may be included at a height at which the stacked interconnects are formed. Such a void may remain until the slits SLT are formed. If the position of the void formed in the insulating film overlaps the position at which the slit is formed, variations in the shape and in the bottom shape among the formed slits SLT may be caused. Failure in forming a slit SLT in an intended shape may become a cause of slit SLT-related malfunction. Similarly, the case where contacts are formed through the insulating film in an area in which a void is formed may also become a cause of contact-related malfunction.

Against this backdrop, in the case where the multiple-stage processing is performed at least three times, the semiconductor memory device 1 according to the embodiment comprises, in an area from which an uppermost layer group LG is removed, a layer group LG in which an overlay is shifted to the positive direction and a layer group LG in which an overlay is shifted to the negative direction.

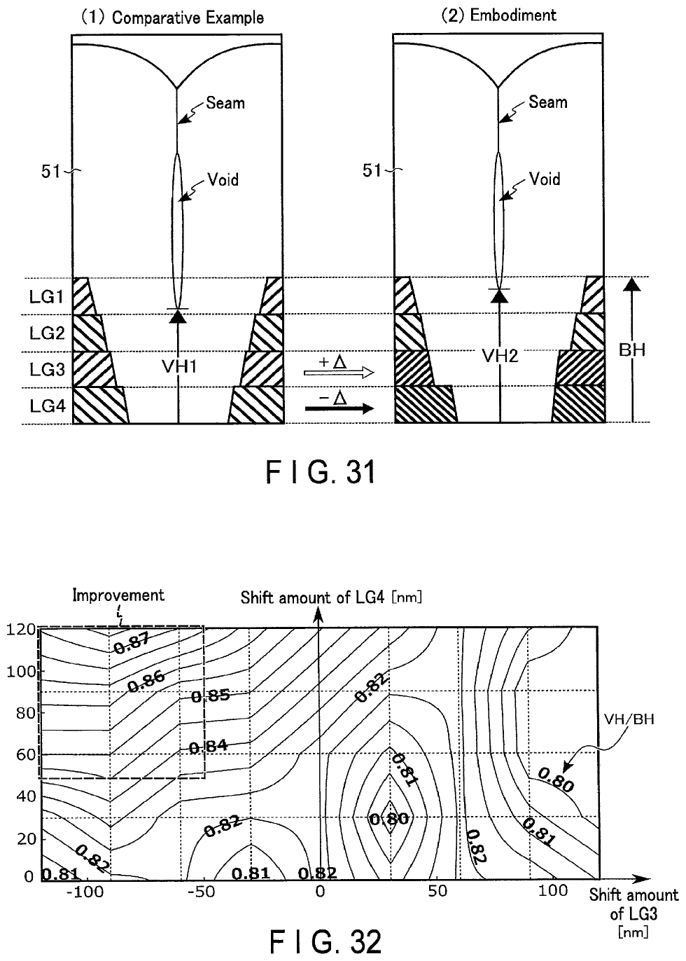

FIG. 31 is schematic views showing examples of a result of the process of embedding insulating film 51 in each of the embodiment and a comparative example. In this example, the layer groups LG1 to LG4 are defined from higher to lower. Each of the layer groups LG1 to LG4 corresponds to a layer on which the multiple-stage processing has been performed. FIG. 31 (1) corresponds to a comparative example and shows a case in which the center positions of the overlay in the multiple-stage processing performed on each of the layer groups LG1 to LG4 are aligned. FIG. 31 (2) corresponds to the present embodiment and shows a case in which the center positions of the overlay of the multiple-stage processing performed on the layer groups LG1 and LG2 are aligned, the center position of the overlay of the multiple-stage processing performed on the layer group LG3 is shifted to the positive direction (+Δ), and the center position of the overlay of the multiple-stage processing performed on the layer group LG4 is shifted to the negative direction (−Δ).

As shown in FIG. 31, by the process of embedding the insulating film 51 into the area on which the multiple-stage processing has been performed in the layer groups LG1 to LG4, a void and a seam may be respectively formed in the present embodiment and the comparative example. The void height VH2 in the case in which the center position of the overlay of each of the layer groups LG3 and LG4 is shifted (FIG. 31 (2)) is higher than the void height VH1 in the case in which the center positions of the overlay of the layer groups LG1 to LG4 (FIG. 31 (1)) are aligned. This is because the insulating film 51 embedded in the concave portion becomes asymmetric in the area of the layer groups LG3 and LG4 as a result of shifting the center positions of the overlay in the layer groups LG3 and LG4. As a result, the surface portions of the insulating film, where the deposition progresses along the opposite inclined portion, is in contact with each other with respect to the Y direction at a higher position in the hookup portion HP. Thus, in the semiconductor memory device 1 according to the embodiment, the position of the void may be higher and the size of the void may be smaller than in the comparative example.

FIG. 32 is a graph showing an example of a simulation result of a void height by the insulating film 51 embedding process. FIG. 32 shows a result of simulation of VH/BH in the case in which the layer groups LG1 to LG4 are provided similarly to the structure shown in FIG. 31 and the shift amount in each of the layer groups LG3 and LG4 changes. “VH” represents a void height. “BH” represents a height of the layer groups LG1 to LG4 as a whole, namely the height of the layer group LG1 from the bottom surface of the layer group LG4. In FIG. 32, the horizontal axis represents a shift amount [nm] of the layer group LG3, the vertical axis represents a shift amount [nm] of the layer group LG4, and the contour lines in the graph represent VH/BH.

As shown in FIG. 32, roughly speaking, VH/BH changes within the range from 0.80 and 0.87. Since VH/BH is a numerical value indicating a void height, it is preferable that VH/BH have a large value. If the shift amount of the layer group LG4 is “0”, the change in the value VH/BH is small, regardless of the shift amount of the layer group LG3 being shifted in the positive direction or the negative direction. Even if the layer group LG3 is shifted to the positive direction and the layer group LG4 is shifted to the positive direction, the change in the value VH/BH is small.

On the other hand, in the case where the layer group LG3 is shifted to the negative direction and the layer group LG4 is shifted to the positive direction, the value VH/BH tends to become larger than in the case where the shift amount of each of the layer groups LG3 and LG4 is “0”. In particular, if the layer group LG3 is shifted by 50 nm or greater in the negative direction and the layer group LG4 is shifted by 50 nm or greater in the positive direction, remarkable improvement in VH/BH can be observed. Specifically, this simulation shows that the result when the shift amount of the layer group LG3 falls within the range of −20 nm to −50 nm and the shift amount of the layer group LG4 falls within the range of +50 nm and +120 nm is good.

As described above, the semiconductor memory device 1 according to the embodiment can improve the embedded status of the insulating film 51 in the area on which the multiple-stage processing is performed several times and can make the height VH of the void formed in the insulating film 51 greater. Furthermore, the semiconductor memory device 1 according to the embodiment can suppress the possibility that the void formed in the insulating film 51 will remain therein and affect later manufacturing steps. As a result, the semiconductor memory device 1 according to the present embodiment can suppress the occurrence of void-related malfunction at a site where the void is formed and can improve the yield of the semiconductor memory device 1.

In the semiconductor memory device 1 according to the embodiment, it suffices that two layer groups LG shifted to the positive and negative directions are two of the layer groups LG besides the uppermost layer group LG. To achieve the effects described in the embodiment, it is preferable that two layer groups LG to be shifted respectively in the positive direction and the negative direction be adjacent to each other. Furthermore, the effects described in the embodiment can be achieved particularly well when the lower-most layer group LG and the layer group LG adjacent thereto make up a combination.

### [4] Modifications, etc.

In the embodiment, the case where a dummy step is formed in the hookup portion HP is described, but the embodiment is not limited thereto. Even when a dummy step is not formed in the hookup portion HP, a structure similar to the one in the embodiment can be adopted. In other words, in the forming of a stepped structure in the hookup portion HP, the same effects as the embodiment can be achieved by performing the multiple-stage processing at least twice with the shifting in the positive and negative sides of the Y direction (for example, the direction in which multiple blocks BLK are arranged).

In the embodiment, the case where the hookup area HA is arranged between the memory areas MA1 and MA2 is described, but the embodiment is not limited thereto. The hookup area HA may be arranged in the vicinity of the outer periphery of the memory cell array 10. In this case, for example two hookup areas HA are provided, and a memory area MA may be arranged between those hookup areas HA. As described in the embodiment, in the case where the hookup area HA is arranged between the memory areas MA1 and MA2, this hookup area HA is preferably arranged in the middle part of the memory cell array 10 area. Thus, a time constant of the change in the voltage applied by the row decoder module 15 to each interconnect (the word lines WL, etc.) of the memory areas MA1 and MA2 may be equalized.

The structure of the memory cell array 10 in the semiconductor memory device 1 according to the embodiment may be an alternative structure. For example, in the hookup area HA, a plurality of stack structures in which stepped structures similar to the stepped areas SA1 to SA4 may be provided in the Z direction in such a manner that the areas on which the multiple-stage processing is performed several times overlap each other while those stack structures are shifted in the X direction.

In the memory areas MA1 and MA2 of the memory cell array 10, the memory pillar MP for example has a structure in which two or more pillars are coupled in the Z direction so as to correspond to the multiple stack structures provided in the Z direction. The memory pillar MP may have a structure in which a pillar corresponding to a select gate line SGD and a pillar corresponding to a word line WL are coupled. Any memory pillar MP and bit line BL as well as any contact CC and conductive layer 26 may be coupled by a plurality of contacts coupled in the Z direction. In this case, a conductive layer may be inserted into a coupled portion of the contacts.

In the drawings used for explanation in the embodiment, the memory pillar MP is illustrated as having the same diameter in the Z direction, but is not limited thereto. For example, the memory pillar MP may have either a tapered or reverse-tapered shape, or a shape having a bloated middle portion (bowed shape). Similarly, each of the slits SLT and SHE may have a tapered or reverse-tapered shape, or even a bowed shape. Moreover, in the foregoing embodiment, each of the memory pillars MP and contacts CC has a circular cross section, but the cross section of each component may be ellipsoidal or any shape.

In the embodiment, the inside of each of the slits SLT and SHE may be composed of a single or a plurality of types of insulators. In this case, a contact corresponding to the source line SL (conductive layer 21) may be provided in the hookup area HA. In the specification, the position of the slit SLT is specified based on the position of, for example, the contact LI. When the slit SLT is composed of an insulator, the position of the slit SLT may be specified by a seam in the slit SLT or a material that remains in the slit SLT at the time of the replacement process.

In the embodiment, the case where circuitry such as the sense amplifier module 16 is provided under the memory cell array 10 is described, but the present invention is not limited thereto. For example, the semiconductor memory device 1 may have a structure in which stacked interconnects such as word lines WL are formed on the semiconductor substrate 20, or a structure in which a chip having the sense amplifier module 16, etc. and a chip having the memory cell array 10 are bonded together. If the semiconductor memory device 1 has the chip-bonded structure, a structure corresponding to the semiconductor substrate 20 may be omitted.

Herein, the term “couple” refers to electrical coupling, and does not exclude interposition of another component. Expressions such as “electrically coupled” cover insulator-interposed coupling that allows for the same operation as electrical coupling without an insulator. The term “pillar” refers to a structure provided in a hole formed in the manufacturing process of the semiconductor memory device 1. The expression “same-layer structure” refers to a structure in which at least the order of formation of layers is the same. The insulating layer may be called an “insulating film”.

In the present specification, the term “area” may be regarded as a configuration included in the semiconductor substrate 20. For example, when the semiconductor substrate 20 is defined as including the memory areas MA1 and MA2 and hookup area HA, the memory areas MA1 and MA2 and hookup area HA are respectively associated with different areas above the semiconductor substrate 20. The “height” corresponds to, for example, a distance between the configuration to be measured and the semiconductor substrate 20 in the Z direction. For the reference for the “height”, a configuration different from the semiconductor substrate 20 may be used. For the reference for “upper” and “upper layer” with respect to the Z direction, a structure other than the semiconductor substrate 20 may be used. For example, in the case of a chip-bonded structure in which the semiconductor substrate 20 is removed, the direction in which the terraced portion faces so as to touch the contact may be associated with “upper”, and a conductive layer in which the terraced portion does not overlap the conductive layer in which a terraced portion is provided may be associated with “upper layer”. The position of the “inclined portion IP” is not necessarily determined by the upper end portion of the inclined portion IP. As the definition of the position of the inclined portion IP, any definition can be adopted as long as the same criteria is adopted for all inclined portions IP formed in different layer groups LG. “Aligned side surfaces of multiple conductive layers” refers to a shape obtained by batch etching of the layers. If the side surfaces of a plurality of conductive layers are aligned, the tapered angles of the side surfaces of the conductive layers may become approximately the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor memory device comprising:
a substrate that includes a first area and a second area, the first area and the second area being arranged in a first direction;
a plurality of first conductive layers arranged in a second direction and separated from each other, the second direction intersecting the first direction, the first conductive layers including a plurality of terraced portions, the terraced portions being provided not to overlap an upper first conductive layer in the second area;
a plurality of first pillars, each provided to penetrate the first conductive layers in the first area, a portion at which one of the first pillars and one of the first conductive layers intersect each other functioning as a memory cell;
an insulating layer provided above the terraced portions; and
a plurality of first contacts, each provided to penetrate the insulating layer, the first contacts being in contact with the terraced portions, respectively, wherein
the first conductive layers include three or more layer groups arranged in the second direction,
the three or more layer groups include a first layer group, a second layer group, and a third layer group, the first layer group being located on an uppermost layer among the three or more layer groups,
the insulating layer includes a first portion, a second portion, and a third portion, the first portion being sandwiched by the first layer group in a third direction which intersects each of the first direction and the second direction, the second portion being sandwiched by the second layer group in the third direction, and the third portion being sandwiched by the third layer group in the third direction,
third-direction side surfaces of the first conductive layers included in the first layer group are aligned in a portion where the first portion and the first layer group are in contact,
third-direction side surfaces of the first conductive layers included in the second layer group are aligned in a portion where the second portion and the second layer group are in contact,
third-direction side surfaces of the first conductive layers included in the third layer group are aligned in a portion where the third portion and the third layer group are in contact, and
with respect to a center position of the first portion in the third direction, a center position of the second portion in the third direction is shifted to one side of the third direction, and a center position of the third portion in the third direction is shifted to the other side of the third direction.

2. The device of claim 1, wherein
among the three or more layer groups, the second layer group and the third layer group are adjacent to each other.

3. The device of claim 2, wherein
a pair of the second layer group and the third layer group is located in a lowermost layer among the three or more layer groups.

4. The device of claim 1, wherein
a shift amount of the center position of the second portion in the third direction toward one side of the third direction with respect to the center position of the first portion in third direction is 50 nm or greater, and
a shift amount of the center position of the third portion in the third direction toward the other side of the third direction with respect to the center position of the first portion in third direction is 50 nm or greater.

5. The device of claim 1, further comprising:
a first member provided to extend in the first direction, the first member dividing, in the third direction, the first to third portions of the insulating layer, and the first conductive layers.

6. The device of claim 5, wherein
the first member includes a second contact and a first insulating film, the second contact being provided to extend in the second direction, the first insulating film being provided on a side surface of the second contact, and the first insulating film insulating the second contact from the first conductive layers.

7. The device of claim 1, wherein
the substrate includes a first stepped area, a second stepped area, a third stepped area, and a fourth stepped area aligned along the first direction within the second area,
the first stepped area includes a plurality of first terraced portions included in the terraced portions and ascending on one side of the first direction,
the second stepped area includes a plurality of second terraced portions included in the terraced portion and ascending on the other side of the first direction, the second stepped area being located in a layer lower than the first stepped area,
the third stepped area includes a plurality of third terraced portions included in the terraced portions and ascending on said one side of the first direction, the third stepped area being located in a layer lower than the second stepped area,
the fourth stepped area includes a plurality of fourth terraced portions included in the terraced portions and ascending on the other side of the first direction, the fourth stepped area being located in a layer lower than the third stepped area.

8. The device of claim 7, wherein
at least one of the first conductive layers corresponding to the first terraced portions is located in a layer higher than the first layer group.

9. The device of claim 1, further comprising:
a plurality of second pillars, each provided to penetrate the first conductive layers, a portion at which one of the second pillars and one of the first conductive layers intersect each other functioning as a memory cell, wherein
the substrate further includes a third area that includes the second pillars, and
the second area is interposed between the first area and the third area in the first direction.

10. The device of claim 9, wherein
the first conductive layers are divided in units of blocks, each of the blocks including a part of each of the first area, the second area, and the third area, and
the insulating layer is arranged every two blocks.

11. The device of claim 10, wherein
the second area includes a fourth area and a fifth area,
the fourth area includes, of a plurality of insulating layers aligned in the third direction, an odd-numbered insulating layer, the fourth area being adjacent to the first area in the first direction, and
the fifth area includes an even-numbered insulating layer of the insulating layers aligned in the third direction, the fifth area being adjacent to the third area in the first direction.

12. The device of claim 11, wherein
the second area includes a contact area in each block, the contact area including a plurality of third contacts that couple interconnects above the first conductive layers to interconnects below the first conductive layers,
two contact areas aligned in the third direction are arranged between the fourth area and the third area, and
two contact areas aligned in the third direction are arranged between the fifth area and the first area.

13. The device of claim 1, further comprising:
a second conductive layer coupled to a lower end of each of the first pillars.

14. The device of claim 13, further comprising:
a plurality of third conductive layers provided between the substrate and the second conductive layer, wherein
the first contacts are electrically coupled to the third conductive layers, respectively.

15. The device of claim 13, further comprising:
a second member that divides, in the first area and in the second area, the first conductive layers in the third direction, wherein
the second member includes a fourth contact and a second insulating film, the fourth contact being provided to extend in the second direction, a bottom of the fourth contact being in contact with the second conductive layer, the second insulating film being provided on a side surface of the fourth contact, and the second insulating film insulating the fourth contact from the first conductive layers.

16. The device of claim 1, wherein:
a width of the insulating layer in the third direction is narrower in the second portion than in the first portion and narrower in the third portion than in the second portion.

17. A method of manufacturing a semiconductor memory device comprising:
forming a stack structure in which a plurality of terraced portions are provided in a middle area in a first direction, the stack structure including a plurality of insulating layers and a plurality of sacrificial members and the insulating layers and the sacrificial members being alternately stacked in a second direction which intersects the first direction;
forming a first mask having an opening corresponding to a first area that includes part of the terraced portions;
etching at a height that includes a plurality of sacrificial members included in at least a first layer group in a batch, using the first mask;
forming a second mask having an opening corresponding to a second area, the second area overlapping at least part of the first area and having a center position in a third direction shifted to one side of the third direction with respect to the first area, the third direction intersecting each of the first direction and the second direction;
etching, in a batch, part of a plurality of sacrificial members included in a second layer group lower than the first layer group, using the second mask;
forming a third mask having an opening corresponding to a third area, the third area overlapping at least part of the first area and at least part of the second area and having a center position in the third direction shifted to the other side of the third direction with respect to the first area;
etching, in a batch, part of a plurality of sacrificial members included in a third layer group lower than the second layer group, using the third mask;
after the batch etching of part of the sacrificial members included in the third layer group, forming an insulating film on a plurality of terraced portions of a plurality of sacrificial members provided in the first layer group, a plurality of terraced portions of a plurality of sacrificial members provided in the second layer group, and a plurality of terraced portions of a plurality of sacrificial members provided in the third group;
after forming the insulating film, forming a slit that divides the stack structure; and
removing the sacrificial members included in the stack structure and embedding a conductor into a space from which the sacrificial members have been removed via the slit.

18. The method of claim 17, further comprising
forming a contact that extends in the second direction through the insulating film in the middle area and that reaches the conductor.

19. The method of claim 18, wherein
a dimension with respect to the third direction of the opening being provided in correspondence to each of the first area, the second area, and the third area is smaller in the second mask than in the first mask, and smaller in the third mask than in the second mask.

20. The method of claim 17, wherein
a shift amount in the second area with respect to one side of the third direction is 50 nm or greater, and
a shift amount in the third area with respect to the other side of he third direction is 50 nm or greater.
